(19) United States
(12) Patent Application Publication
(10) Pub. No.: US 2026/0157239 A1
(43) Pub. Date: Jun. 4, 2026

(54) STACKED MEMORY DEVICES AND SEMICONDUCTOR SYSTEM

(71) Applicant: SK hynix Inc., Icheon-si Gyeonggi-do (KR)

(72) Inventors: Joon Yong CHOI, Icheon-si Gyeonggi-do (KR); Choung Ki SONG, Icheon-si Gyeonggi-do (KR); Jong Moo LEE, Icheon-si Gyeonggi-do (KR)

(73) Assignee: SK hynix Inc., Icheon-si Gyeonggi-do (KR)

(21) Appl. No.: 19/383,452

(22) Filed: Nov. 7, 2025

Related U.S. Application Data
(63) Continuation-in-part of application No. 19/382,036, filed on Nov. 6, 2025.
(63) Continuation-in-part of application No. 19/317,348, filed on Sep. 3, 2025.
(60) Provisional application No. 63/720,380, filed on Nov. 14, 2024.
(60) Provisional application No. 63/728,952, filed on Dec. 6, 2024.
(60) Provisional application No. 63/826,717, filed on Jun. 19, 2025.
(60) Provisional application No. 63/828,634, filed on Jun. 23, 2025.

(51) Int. Cl. H10W 90/20; H10B 80/00; H10D 80/30; H10W 20/20; H10W 70/60; H10W 90/15

(52) U.S. Cl. CPC H10W 90/297; H10B 80/00; H10D 80/30; H10W 20/213; H10W 90/155; H10W 90/275; H10W 70/611

(57) ABSTRACT

A semiconductor system including a control device including a first area and a second area. The first area includes an internal interface area disposed in a first direction and the second area comprising an internal input and output line disposed in a second direction. The control device includes a memory device stacked on the second area and configured to input and output data. The internal interface area intersecting with the internal input and output line. The control device and the memory device are configured to input and output the data to and from the internal interface area through the internal input and output line.

### CROSS-REFERENCES TO RELATED APPLICATIONS

This application is a continuation-in-part application of U.S. patent application Ser. No. 19/382,036 filed on Nov. 6, 2025, which claims the benefit of priority under 35 U.S.C. § 119(e) to U.S. Patent Provisional Application 63/826,717 filed on Jun. 19, 2025, and U.S. Patent Provisional Application 63/728,952 filed on Dec. 6, 2024, and this application is a continuation-in-part application of U.S. patent application Ser. No. 19/317,348 filed on Sep. 3, 2025, which claims the benefit of priority under 35 U.S.C. § 119(e) to U.S. Patent Provisional Application 63/828,634 filed on Jun. 23, 2025, and U.S. Patent Provisional Application 63/720,380 filed on Nov. 14, 2024, the entire contents of all of the above applications are incorporated herein by reference in their entirety.

### BACKGROUND

### 1. Technical Field

The present disclosure generally relates to a semiconductor system, and more particularly, to stacked memory devices and semiconductor systems.

### 2. Related Art

Recently, stacked memory systems such as high bandwidth memory (HBM) devices are used in a wide range of applications due to their high bandwidths and energy efficiency. Unlike conventional memory systems that use parallel data buses, the stacked memory system includes a stacked memory device including a base chip and a plurality of memory chips interconnected by through silicon vias (TSVs). The stacked memory device includes a physical interface, such as a physical layer to communicate with a processor. The physical layer is designed for high-speed data transmission and efficient communication.

### SUMMARY

In an embodiment, a semiconductor system comprising including a control device and a memory device, the control device in which a first area and a second area are formed and comprising the first area comprising an internal interface area disposed in a first direction and the second area comprising an internal input and output line disposed in a second direction and the memory device stacked on the second area and configured to input and output data, wherein the internal interface area and the internal input and output line are connected in an orthogonal direction to each other, the control device and the memory device input and output the data to and from the internal interface area through the internal input and output line, and a setting space is set vertically to the first area.

In an embodiment, a semiconductor system comprising a control device and a memory device, the control device in which first to third areas are formed and comprising the first area comprising a first internal interface area disposed in a first direction, the second area comprising first and second internal input and output lines disposed in a second direction, and the third area comprising a second internal interface area disposed in the first direction and the memory device stacked on the second area and configured to input and output first and second data, wherein the first and second internal interface areas and the first and second internal input and output lines are connected in an orthogonal direction to each other, the control device and the memory device input and output the first and second data to and from the first and second internal interface areas through the first and second internal input and output lines, a first setting space is set vertically to the first area, a second setting space is set vertically to the second area, and a third setting space is set vertically to the third area.

In an embodiment, a semiconductor system comprising a control device and a memory device, the control device in which a first area and a second area are formed and comprising the first area comprising an internal interface area disposed in a first direction and the second area comprising first and second internal input and output lines disposed in a second direction and the memory device stacked on the second area and configured to input and output data, wherein the internal interface area and the first and second internal input and output lines are connected in an orthogonal direction to each other, the control device and the memory device input and output the data to and from the internal interface area through the first and second internal input and output lines, a first setting space is set vertically to the first area, and a second setting space is set vertically to the second area.

In an embodiment, a semiconductor system comprising a control device and a memory device, the control device in which first to third areas are formed and comprising the first area comprising a first internal interface area disposed in a first direction, the second area comprising an internal input and output line disposed in a second direction, and the third area comprising a second internal interface area disposed in the first direction and the memory device stacked on the second area and configured to input and output first and second data, wherein the first and second internal interface areas and the internal input and output line are connected in an orthogonal direction to each other, the control device and the memory device input and output the first and second data to and from the first and second internal interface areas through the internal input and output line, a first setting space is set vertically to the first area, a second setting space is set vertically to the second area, and a third setting space is set vertically to the third area.

### BRIEF DESCRIPTION OF THE DRAWINGS

FIG. 1 illustrates a stacked memory device according to an embodiment of the present disclosure.

FIG. 2 illustrates an example of the arrangement of areas included in a base die.

FIG. 3 illustrates a stacked memory device according to an embodiment of the present disclosure.

FIG. 4 illustrates a stacked memory device according to an embodiment of the present disclosure.

FIGS. 5 to 8 illustrate examples of the arrangement of areas included in base dies.

FIG. 9 illustrates a stacked memory system according to an embodiment of the present disclosure.

FIG. 10 illustrates a semiconductor system according to an embodiment of the present disclosure.

FIG. 11 illustrates a control device according to an embodiment of the present disclosure.

FIG. 12 illustrates first and second memory devices according to an embodiment of the present disclosure.

FIG. 13 illustrates the control device according to an embodiment of the present disclosure.

FIG. 14 illustrates the first and second memory devices according to an embodiment of the present disclosure.

FIG. 15 illustrates the control device according to an embodiment of the present disclosure.

FIG. 16 illustrates the first and second memory devices according to an embodiment of the present disclosure.

FIG. 17 illustrates a semiconductor system according to an embodiment of the present disclosure.

FIGS. 18 and 19 are block diagrams illustrating constructions of semiconductor systems according to an embodiment of the present disclosure.

FIG. 20 is a block diagram illustrating a construction of an HMB device according to an embodiment of the present disclosure.

FIG. 21 is a block diagram illustrating a construction of a control device according to an embodiment of the present disclosure.

FIG. 22 is a block diagram illustrating a construction of a control device according to an embodiment of the present disclosure.

FIG. 23 is a block diagram illustrating a construction of a memory device according to an embodiment of the present disclosure.

FIG. 24 is a block diagram illustrating a construction of a control device according to an embodiment of the present disclosure.

FIG. 25 is a block diagram illustrating a construction of a control device according to an embodiment of the present disclosure.

FIG. 26 is a block diagram illustrating a construction of a memory device according to an embodiment of the present disclosure.

FIG. 27 is a block diagram illustrating a construction of a control device according to an embodiment of the present disclosure.

FIG. 28 is a block diagram illustrating a construction of a control device according to an embodiment of the present disclosure.

FIG. 29 is a block diagram illustrating a construction of a memory device according to an embodiment of the present disclosure.

### DETAILED DESCRIPTION

Terms such as “first” and “second” are used to distinguish between various elements and do not imply size, order, priority, quantity, or importance of the elements. For example, a first element may be named as a second element in one example, and the second element may be named as a first element in another example.

When one component is identified as “connected” to another component, the components may be connected directly or through an intervening component between the components. When two components are identified as “directly connected,” one component is directly connected to the other component without an intervening component between the two components. When one component is referred to as being on another component, it should be understood that the components may be directly on each other or on each other through another component interposed therebetween. In contrast, when one component is referred to as being directly on another component, it should be understood that the components are directly on each other without another component interposed therebetween.

Embodiments of the present disclosure are described below with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

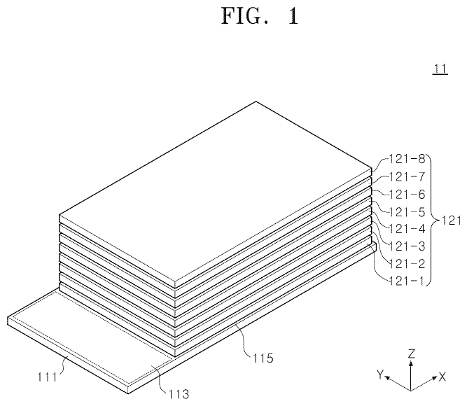

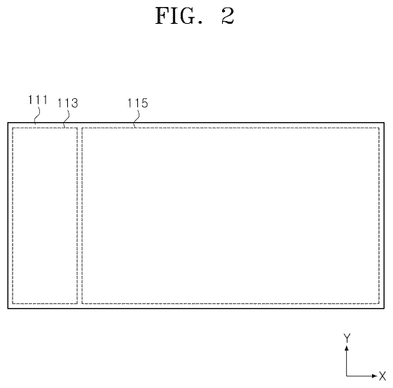

FIG. 1 illustrates a stacked memory device 11 according to an embodiment of the present disclosure, and FIG. 2 illustrates an example of the arrangement of a first area 113 and a second area 115 included in a base die 111.

As illustrated in FIG. 1, the stacked memory device 11 includes the base die 111 and a core die group 121. As illustrated in FIGS. 1 and 2, the first area 113 and the second area 115 refer to areas on the XY plane of the base die 111. The first area 113 and the second area 115 are sequentially arranged adjacent to each other in the X direction.

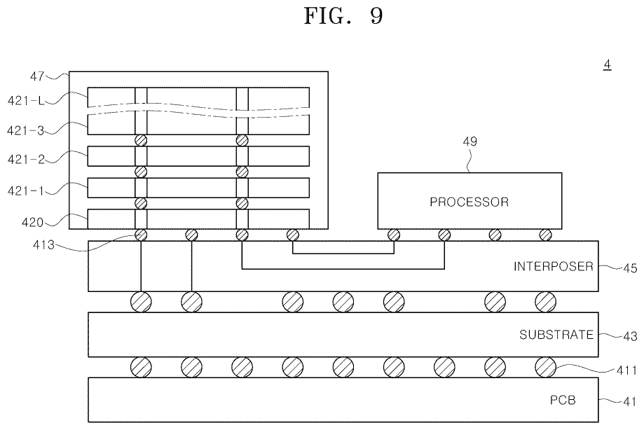

A physical layer that controls the transmission of signals (e.g., data, commands, and addresses) through a plurality of channels between the core die group 121 and a processor (e.g., a processor 49 in FIG. 9) may be disposed beneath the first area 113 of the base die 111. According to embodiments, circuits that operate in a high-temperature state due to the frequent input/output of signals among internal circuits included in the base die 111 may be disposed beneath the first area 113 of the base die 111. No structure that dissipates heat is stacked in the Z direction from the first area 113 of the base die 111. That is, an empty space is provided in the Z direction from the first area 113 of the base die 111. Thus, in an embodiment, heat generated when the internal circuits, located beneath the first area 113 of the base die 111, operate can be dissipated in the Z direction from the first area 113.

A plurality of core dies 121-1 to 121-8 of the core group 121 is stacked in the Z direction from the second area 115. The core group 121 includes a first core die 121-1, a second core die 121-2, a third core die 121-3, a fourth core die 121-4, a fifth core die 121-5, a sixth core die 121-6, a seventh core die 121-7, and an eighth core die 121-8. The first core die 121-1 is stacked in the Z direction from the second area 115, the second core die 121-2 is stacked in the Z direction from the first core die 121-1, the third core die 121-3 is stacked in the Z direction from the second core die 121-2, the fourth core die 121-4 is stacked in the Z direction from the third core die 121-3, the fifth core die 121-5 is stacked in the Z direction from the fourth core die 121-4, the sixth core die 121-6 is stacked in the Z direction from the fifth core die 121-5, the seventh core die 121-7 is stacked in the Z direction from the sixth core die 121-6, and the eight core die 121-8 is stacked in the Z direction from the seventh core die 121-7.

Various control circuits that control the core die group 121 may be disposed beneath the second area 115 of the base die 111. The control circuits disposed beneath the second area 115 may include write control circuits (not shown) that store data in the core die group 121 and read control circuits (not shown) that output data from the core die group 121.

As described above, an empty space is provided in the Z direction from the first area 113 of the base die 111, and heat generated due to an operation of the internal circuits located beneath the first area 113 is dissipated in the Z direction from the first area 113. An embodiment of this configuration helps prevent or mitigate the internal temperature of the base die 111 from rising excessively.

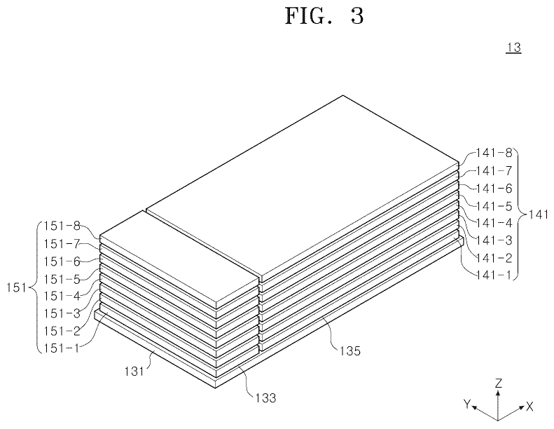

FIG. 3 illustrates a stacked memory device 13 according to an embodiment of the present disclosure.

As illustrated in FIG. 3, the stacked memory device 13 includes a base die 131 and a core die group 141. As in an embodiment described in relation to FIG. 2, the base die 131 includes a first area 133 and a second area 135 on the XY plane.

A physical layer that controls the transmission of signals (e.g., data, commands, and addresses) through a plurality of channels between the core die group 141 and a processor (e.g., a processor 49 in FIG. 9) may be disposed beneath the first area 133 of the base die 131. According to embodiments, circuits that operate in a high-temperature state due to the frequent input/output of signals, among internal circuits included in the base die 131, may be disposed beneath the first area 133 of the base die 131. In an embodiment, a plurality of dummy dies 151-1 to 151-8 of a dummy die group 151 is stacked to dissipate heat in the Z direction from the first area 133 of the base die 131. The dummy die group 151 includes a first dummy die 151-1, a second dummy die 151-2, a third dummy die 151-3, a fourth dummy die 151-4, a fifth dummy die 151-5, a sixth dummy die 151-6, a seventh dummy die 151-7, and an eighth dummy die 151-8. The first dummy die 151-1 is stacked in the Z direction from the first area 133, the second dummy die 151-2 is stacked in the Z direction from the first dummy die 151-2, the third dummy die 151-3 is stacked in the Z direction from the second dummy die 151-2, the fourth dummy die 151-4 is stacked in the Z direction from the third dummy die 151-3, the fifth dummy die 151-5 is stacked in the Z direction from the fourth dummy die 151-4, the sixth dummy die 151-6 is stacked in the Z direction from the fifth dummy die 151-5, the seventh dummy die 151-7 is stacked in the Z direction from the sixth dummy die 151-6, and the eighth dummy die 151-8 is stacked in the Z direction from the seventh dummy die 151-7. In an embodiment, the dummy dies 151-1 to 151-8 of the dummy die group 151 are stacked in the Z direction from the first area 133 of the base die 131, and thus, heat generated from the internal circuits located beneath the first area 133 of the base die 131 during operation can be dissipated in the Z direction from the first area 133 through the dummy die group 151. In an embodiment, the first dummy die 151-1, the second dummy die 151-2, the third dummy die 151-3, the fourth dummy die 151-4, the fifth dummy die 151-5, the sixth dummy die 151-6, the seventh dummy die 151-7, and the eighth dummy die 151-8 are connected through a plurality of through vias and a plurality of micro-bump pads to each other to facilitate heat dissipation.

A plurality of core dies 141-1 to 141-8 of the core die group 141 is stacked in the Z direction from the second area 135. The core die group 141 includes a first core die 141-1, a second core die 141-2, a third core die 141-3, a fourth core die 141-4, a fifth core die 141-5, a sixth core die 141-6, a seventh core die 141-7, and an eighth core die 141-8. The first core die 141-1 is stacked in the Z direction from the second area 135, the second core die 141-2 is stacked in the Z direction from the first core die 141-1, the third core die 141-3 is stacked in the Z direction from the second core die 141-2, the fourth core die 141-4 is stacked in the Z direction from the third core die 141-3, the fifth core die 141-5 is stacked in the Z direction from the fourth core die 141-4, the sixth core die 141-6 is stacked in the Z direction from the fifth core die 141-5, the seventh core die 141-7 is stacked in the Z direction from the sixth core die 141-6, and the eighth core die 141-8 is stacked in the Z direction from the seventh core die 141-7.

Various control circuits that control the core die group 141 may be disposed beneath the second area 135 of the base die 131. The control circuits disposed beneath the second area 135 may include write control circuits (not shown) that store data in the core die group 141 and read control circuits (not shown) that output data from the core die group 141.

As described above, in an embodiment, the dummy dies of the dummy die group 151 are stacked in the Z direction from the first area 133 of the base die 131, and thus, the heat generated during operation of the internal circuits located beneath the first area 133 can be dissipated through the dummy die group 151 in the Z direction from the first area 133. In an embodiment, this configuration helps prevent or mitigate the internal temperature of the base die 131 from rising excessively.

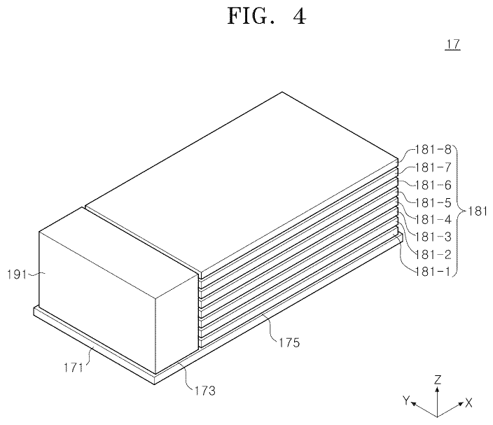

FIG. 4 illustrates a stacked memory device 17 according to an embodiment of the present disclosure.

As illustrated in FIG. 4, the stacked memory device 17 includes a base die 171 and a core die group 181. As in an embodiment illustrated in FIG. 2, the base die 171 includes a first area 173 and a second area 175 on the XY plane of the base die 171.

A physical layer that controls the transmission of signals (e.g., data, commands, and addresses) through a plurality of channels between the core die group 181 and a processor (e.g., a processor 49 in FIG. 9) may be disposed beneath the first area 173 of the base die 171. According to embodiments, circuits that operate in a high-temperature state due to the frequent input/output of signals, among internal circuits included in the base die 171, may be disposed beneath the first area 173 of the base die 171. A dummy die 191 is disposed to dissipate heat in the Z direction from the first area 173 of the base die 171.

A plurality of core dies 181-1 to 181-8 of the core die group 181 is stacked in the Z direction from the second area 175. The core die group 181 includes a first core die 181-1, a second core die 181-2, a third core die 181-3, a fourth core die 181-4, a fifth core die 181-5, a sixth core die 181-6, a seventh core die 181-7, and an eighth core die 181-8. The first core die 181-1 is stacked in the Z direction from the second area 175. The second core die 181-2 is stacked in the Z direction from the first core die 181-1, the third core die 181-3 is stacked in the Z direction from the second core die 181-2, the fourth core die 181-4 is stacked in the Z direction from the third core die 181-3, the fifth core die 181-5 is stacked in the Z direction from the fourth core die 181-4, the sixth core die 181-6 is stacked in the Z direction from the fifth core die 181-5, the seventh core die 181-7 is stacked in the Z direction from the sixth core die 181-6, and the eighth core die 181-8 is stacked in the Z direction from the seventh core die 181-7.

Various control circuits that control the core die group 181 may be disposed beneath the second area 175 of the base die 171. The control circuits disposed beneath the second area 175 may include write control circuits (not shown) that store data in the core die group 181 and read control circuits (not shown) that output data from the core die group 181.

As discussed above, in an embodiment, the dummy die 191 is disposed in the Z direction from the first area 173 of the base die 171, and thus, the heat generated from the internal circuits located beneath the first area 173 during operation can be dissipated through the dummy die 191 in the Z direction from the first area 173. In an embodiment, this configuration helps prevent or mitigate the internal temperature of the base die 171 from rising excessively.

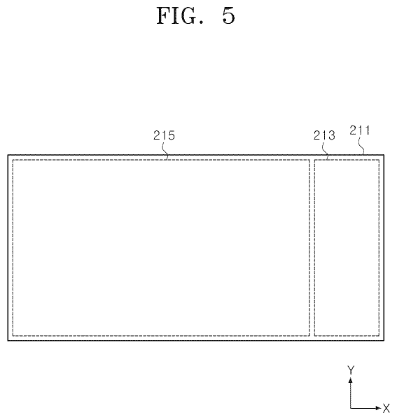

FIGS. 5 to 8 illustrate examples of the arrangement of areas included in a base die.

As illustrated in FIG. 5, a base die 211 includes a first area 213 and a second area 215 on the XY plane. The first area 213 and the second area 215 are sequentially arranged adjacent to each other in the X direction. The first area 213 may correspond to the first area 113 as illustrated in FIGS. 1 and 2 and may correspond to the first area 133 as illustrated in FIG. 3 and the first area 133 as illustrated in FIG. 3. Accordingly, in an embodiment, a physical layer that controls the transmission of signals (e.g., data, commands, and addresses) through a plurality of channels may be disposed beneath the first area 213, and an empty space may be provided on the first area 213 or at least one dummy die may be disposed on the first area 213, thereby dissipating the heat generated in internal circuits beneath the first area 213.

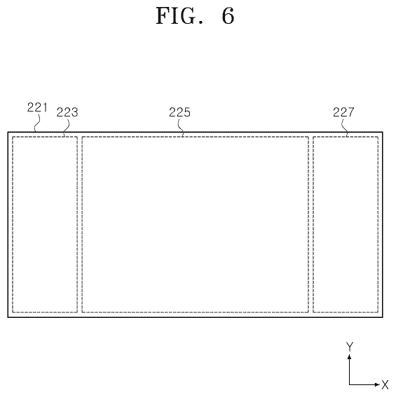

As illustrated in FIG. 6, a first area 223, a second area 225, and a third area 227 are arranged on the XY plane of a base die 221. The first area 223, the second area 225, and the third area 227 are arranged to be adjacent to each other in the X direction. The first area 223 and the third area 227 may correspond to the first area 113 as illustrated in FIGS. 1 and 2, the first area 133 as illustrated in FIG. 3, and the first area 173 as illustrated in FIG. 4. Accordingly, a physical layer that controls the transmission of signals (e.g., data, commands, and addresses) through a plurality of channels may be disposed beneath the first area 223 and the third area 227, and an empty space may be provided on the first area 223 and the third area 227 or at least one dummy die may be disposed on the first area 223 and the third area 227, thereby, in an embodiment, dissipating the heat generated in the internal circuits beneath the first area 223 and the third area 227.

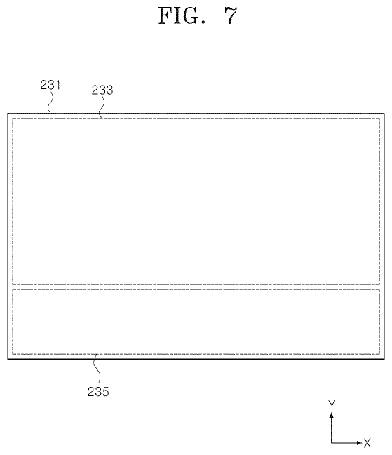

As illustrated in FIG. 7, a first area 235 and a second area 233 are arranged on the XY plane of a base die 231. The first area 235 and the second area 233 are arranged to be adjacent in the Y direction. The first area 235 may correspond to the first area 113 as illustrated in FIGS. 1 and 2, the first area 133 as illustrated in FIG. 3, and the first area 173 as illustrated in FIG. 4. Accordingly, a physical layer that controls the transmission of signals (e.g., data, commands, and addresses) through a plurality of channels may be disposed beneath the first area 235, and an empty space may be provided on the first area 235 or at least one dummy die may be disposed on the first area 235, thereby, in an embodiment, dissipating the heat generated in the internal circuits beneath the first area 235.

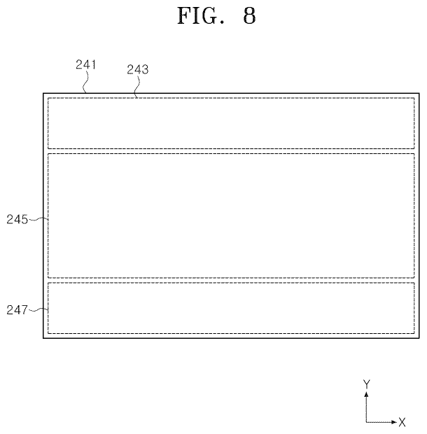

As illustrated in FIG. 8, a first area 243, a second area 245, and a third area 247 are arranged on the XY plane of a base die 241. The third area 247, the second area 245, and the first area 243 are sequentially arranged in the Y direction. Each of the first area 243 and the third area 247 may correspond to the first area 113 as illustrated in FIGS. 1 and 2, the first area 133 as illustrated in FIG. 3, and the first area 173 as illustrated in FIG. 4. Accordingly, a physical layer that controls the transmission of signals (e.g., data, commands, and addresses) through a plurality of channels may be disposed beneath the first area 243 and the third area 247, and empty spaces may be provided on the first area 243 and the third area 247 or at least one dummy die may be disposed on the first area 243 and the third area 247, thereby, in an embodiment, dissipating the heat generated in the internal circuits beneath the first area 243 and the third area 247.

FIG. 9 illustrates a memory system 4 according to an embodiment of the present disclosure.

As illustrated in FIG. 9, the memory system 4 includes a printed circuit board (PCB) 41, a substrate 43, an interposer 45, a memory device 47, and a processor 49.

The printed circuit board 41 connects various electronic components to form electronic circuits. The electronic circuits include the memory system 4. A copper (Cu) layer, a solder mask, a silk screen, and so forth are formed on the printed circuit board 41. Circuit paths that transmit or transfer signals or power are formed in the copper (Cu) layer. In an embodiment, the solder mask prevents or mitigates damage to the circuits and protects a specific area in which components are soldered. The silk screen indicates a location or information for the electronic components as characters or symbols printed on a surface of the printed circuit board 41.

The substrate 43 is disposed over the printed circuit board 41 with bump pads (e.g., bump pads 411) therebetween and mechanically supports the interposer 45, the memory device 47, and the processor 49. The substrate 43 functions as a physical base for the printed circuit board 41 and is an insulator. The substrate 43 may include materials, such as FR4 that is an insulator made of fiberglass and epoxy resin, ceramics that can withstand high temperatures, have appropriate thermal conductivity properties, and are used in high-frequency circuits, polyimide that is used as a basic material for flexible PCBs due to flexible characteristics, and the like.

The interposer 45 is disposed over the substrate 43 with bump pads therebetween and includes wiring that connects electronic components (e.g., the memory device 47 and the processor 49) that have form factors or pin arrangements that do not match or have different spacing. The interposer 45 converts signals from different interfaces, such as DDR, HBM, and PCIe.

The memory device 47 is disposed over the interposer 45 with pads (e.g., micro bump pads 413) therebetween. The memory device 47 stores data received from the processor 49 or outputs data stored therein to the processor 49 under the control of the processor 49. The memory device 47 includes a base die 420 and a plurality of core dies 421-1 to 421-L, where L is an integer greater than 1. The core dies 421-1 to 421-L are stacked over the base die 420 with micro bump pads in between. The base die 420 and the core dies 421-1 to 421-L are vertically connected to each other using through vias and micro bump pads. The base die 420 controls efficient data transmission between the processor 49 and the core dies 421-1 to 421-L. The base die 420 receives input/output power voltage (voltage drain for IO also referred to as output stage drain power voltage) VDDQ as an operating voltage utilized during the operation of internal circuits included in the base die 420. The base die 420 receives the input/output power voltage VDDQ from the printed circuit board 41 through the substrate 43 and the interposer 45. The input/output power voltage VDDQ is a voltage supplied to buffers that transmit data and is distinguished or different from the power supply voltage VDD. The core dies 421-1 to 421-L use a peripheral voltage VPERI as an operating voltage during the operation of the internal circuits included in the core dies 421-1 to 421-L. The core dies 421-1 to 421-L generate the peripheral voltage VPERI from the input/output power voltage VDDQ received through the base die 420. The core dies 421-1 to 421-L generate the peripheral voltage VPERI at a voltage level lower than the level of the input/output power voltage VDDQ and use the peripheral voltage VPERI as an operating voltage. Each of the core dies 421-1 to 421-L includes a plurality of channel areas, for example, eight channel areas or forty-six channel areas that operate independently. Each of the plurality of channel areas is allocated with a channel operating independently to receive or transmit data. The number L of core dies 421-1 to 421-L may be four, eight, thirty-two, forty-six, and so forth. For example, when each of the core dies 421-1 to 421-12 has eight channels, the core dies 421-1 to 421-4, the core dies 421-5 to 421-8, and the core dies 421-9 through 421-12 each include thirty-two channel areas and transmit and receive data with the processor 49 in units of a rank including thirty-two channels.

The memory device 47 may be implemented with the stacked memory device 11 as illustrated in FIG. 1, the stacked memory device 13 as illustrated in FIG. 3, and stacked memory device 17 as illustrated in FIG. 4. The base die 420 may be implemented with the base die 111 as illustrated in FIGS. 1 and 2, the base die 131 as illustrated in FIG. 3, the base die 171 as illustrated in FIG. 4, the base die 211 as illustrated in FIG. 5, the base die 221 as illustrated in FIG. 6, the base die 231 as illustrated in FIG. 7, and the base die 241 as illustrated in FIG. 8.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. The scope of the present disclosure is not limited to the descriptions. All changes within the meaning and range of equivalency of the claims are included within their scope.

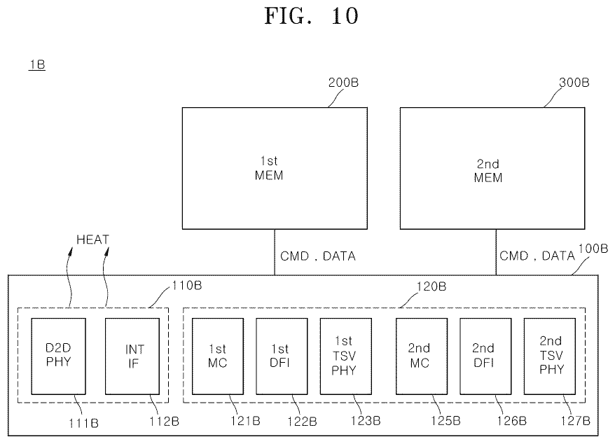

FIG. 10 illustrates a semiconductor system 1B according to an embodiment of the present disclosure. As illustrated in FIG. 10, the semiconductor system 1B may include a control device 100B, a first memory device (1st MEM) 200B, and a second memory device (2nd MEM) 300B. The control device 100B may be implemented with the base die 111 of FIGS. 1 and 2. The control device 100B may be implemented with the base die 131 of FIG. 3. The control device 100B may be implemented with the base die 171 of FIG. 4.

The control device 100B may generate a command CMD and data DATA. The control device 100B may output the command CMD and the data DATA to the first memory device 200B and the second memory device 300B. The control device 100B may receive the data DATA from the first memory device 200B and the second memory device 300B. The control device 100B may be a base chip or a controller that controls operations of the first memory device 200B and the second memory device 300B.

The control device 100B may include a first area 110B and a second area 120B. The first area 110B may be set as an area where the command CMD and the data DATA are generated. The first area 110B may be set as an area from where heat is generated when the command CMD and the data DATA are generated. The second area 120B is an area where the command CMD and the data DATA are received from the first area 110B. The second area 120B is an area from where the command CMD and the data DATA are output and transmitted to the first memory device 200B and the second memory device 300B. The upper part of the first area 110B can be set as a first setting space.

The first area 110B may include a physical area (D2D PHY) 111B and an internal interface area (INT IF) 112B.

The physical area 111B may generate the command CMD and the data DATA based on a signal that is received from an external device (e.g., various devices, such as a host, a processor, and a test device). The physical area 111B may output the command CMD and the data DATA to the internal interface area 112B. The physical area 111B may be a physical layer (PHY) that is responsible for the generation, transmission, reception, and physical connection of signals and data between the external device and the control device 100B.

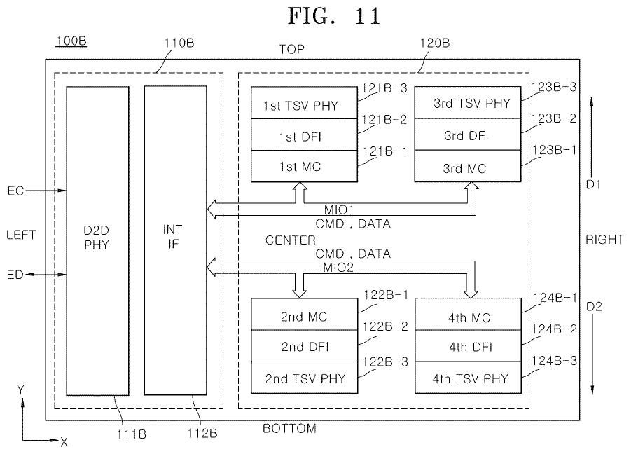

The internal interface area 112B may receive the command CMD and the data DATA from the physical area 111B. The internal interface area 112B may output the command CMD and the data DATA to internal input and output lines (MIO1 and MIO2 in FIG. 11) by adjusting the input and output sequence of the command CMD and the data DATA. The internal interface area 112B may be an interface whereby the timing and sequence of signals that are transmitted between a physical layer (PHY) and internal circuits are defined and the signals are input and output. The internal interface area 112B and the internal input and output lines (MIO1 and MIO2 in FIG. 11) may be implemented in a network-on-chip (NoC). The NoC may be set as a transmission path that connects various internal circuits within a chip.

The second area 120B may include a first memory controller (1st MC) 121B, a first base interface area (1st DFI) 122B, a first base TSV area (1st TSV PHY) 123B, a second memory controller (2nd MC) 125B, a second base interface area (2nd DFI) 126B, a second

### Base Tsv Area (2nd Tsv Phy) 127b.

The first memory controller 121B may receive the command CMD and the data DATA through the internal input and output lines (MIO1 and MIO2 in FIG. 11). The first memory controller 121B may output the command CMD and the data DATA that control an operation of the first memory device 200B.

The first base interface area 122B may receive the command CMD and the data DATA from the first memory controller 121B. The first base interface area 122B may output the command CMD and the data DATA to the first base TSV area 123B by adjusting the input and output sequence of the command CMD and the data DATA.

The first base TSV area 123B may receive the command CMD and the data DATA from the first base interface area 122B. The first base TSV area 123B may output the command CMD and the data DATA to the first memory device 200B through a plurality of TSVs.

The second memory controller 125B may receive the command CMD and the data DATA through the internal input and output lines (MIO1 and MIO2 in FIG. 11). The second memory controller 125B may output the command CMD and the data DATA that control an operation of the second memory device 300B.

The second base interface area 126B may receive the command CMD and the data DATA from the second memory controller 125B. The second base interface area 126B may output the command CMD and the data DATA to the second base TSV area 127B by adjusting the input and output sequence of the command CMD and the data DATA.

The second base TSV area 127B may receive the command CMD and the data DATA from the second base interface area 126B. The second base TSV area 127B may output the command CMD and the data DATA to the second memory device 300B through a plurality of TSVs.

The first memory device 200B may receive the command CMD and the data DATA from the first base TSV area 123B. The first memory device 200B may perform an internal operation based on the command CMD and the data DATA. The first memory device 200B may store the data DATA based on the command CMD after the start of a write operation. The first memory device 200B may output the data DATA that are stored based on the command CMD after the start of a read operation. The first memory device 200B may be a memory device wherein a plurality of core chips is stacked.

The second memory device 300B may receive the command CMD and the data DATA from the second base TSV area 127B. The second memory device 300B may perform an internal operation based on the command CMD and the data DATA. The second memory device 300B may store the data DATA based on the command CMD after the start of a write operation. The second memory device 300B may output the data DATA that are stored based on the command CMD after the start of a read operation. The second memory device 300B may be a memory device wherein a plurality of core chips is stacked.

The first memory device 200B and the second memory device 300B may be disposed on the second area 120B of the control device 100B. The first memory device 200B and the second memory device 300B may be vertically stacked on the second area 120B of the control device 100B. For example, the first memory device 200B and the second memory device 300B may be on the control device 100B through another component interposed therebetween. For example, the first memory device 200B and the second memory device 300B may be located vertically over the control device 100B, at least partially, and connected to the control device 100B through another component interposed therebetween. For example, the first memory device 200B and the second memory device 300B may be directly on the control device 100B without another component interposed therebetween. For example, the first memory device 200B and the second memory device 300B may be located vertically on the control device 100B, at least partially, without another component interposed therebetween. The first memory device 200B and the second memory device 300B may be horizontally disposed on the second area 120B of the control device 100B. The first memory device 200B and the second memory device 300B are connected to the control device 100B in common, and may input and output the data DATA having the same bandwidth. The bandwidth may be set as the amount of data that are input and output for a preset time.

The sum of the lengths of first memory device 200B and the second memory device 300B may be shorter than the length of the second area 120B of the control device 100B. The control device 100B may have a length that is longer than the sum of the lengths of first memory device 200B and the second memory device 300B by the first area 110B.

As described above, the semiconductor system 1B according to an embodiment of the present disclosure can increase the bandwidth because the first memory device 200B and the second memory device 300B are connected to the control device 100B in common and input and output the data DATA. The semiconductor system 1B, in an embodiment, can prevent or mitigate heat, caused from an area in which the command CMD and the data DATA are generated, from being diffused to a memory device because a memory device (e.g., 200B, 300B) is not stacked above the area in which the command CMD and the data DATA are generated.

FIG. 11 illustrates the control device 100B according to an embodiment of the present disclosure. As illustrated in FIG. 11, the control device 100B may include the first area 110B and the second area 120B.

The first area 110B may include the physical area 111B and the internal interface area 112B.

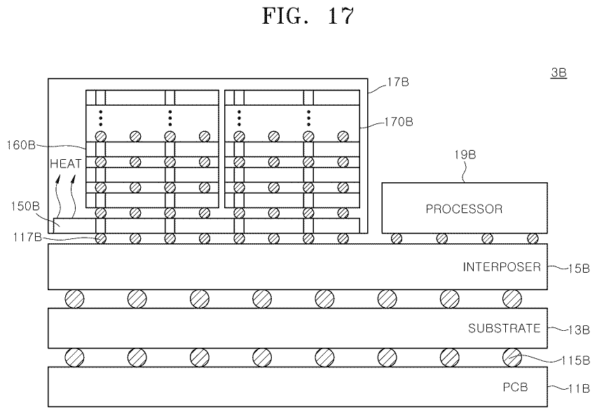

The physical area 111B may generate the command CMD by receiving an external command EC from an external device (e.g., a processor in FIG. 17). The physical area 111B may generate the command CMD by buffering or decoding the external command EC. The external command EC and the command CMD each have been illustrated as one signal, but may each include a plurality of bits. The physical area 111B may generate the data DATA by receiving external data ED from an external device (e.g., the processor in FIG. 17). The physical area 111B may generate the external data ED by receiving data DATA from the internal interface area 112B. The physical area 111B may output the external data ED to the external device (e.g., the processor in FIG. 17). The external data ED and the data DATA each have been illustrated as one signal but may include a plurality of bits. In an embodiment, the external command EC and the external data ED are received externally from the first and second areas.

The internal interface area 112B may receive the command CMD and the data DATA from the physical area 111B. The internal interface area 112B may output the command CMD and the data DATA to the first internal input and output line MIO1 by adjusting the input and output sequence of the command CMD that controls operations of the first memory device 200B and the second memory device 300B and the data DATA. The internal interface area 112B may output the command CMD and the data DATA to the second internal input and output line MIO2 by adjusting the input and output sequence of the command CMD that controls operations of the first memory device 200B and the second memory device 300B and the data DATA. The first internal input and output line MIO1 and the second internal input and output line MIO2 may be disposed in a central area CENTER of the control device 100B.

The first area 110B may be set as an area in which the command CMD and the data DATA are generated. The first area 110B may be set as an area in which heat is generated when the command CMD and the data DATA are generated. The first area 110B may be disposed in a left area LEFT of the control device 100B in an X axis.

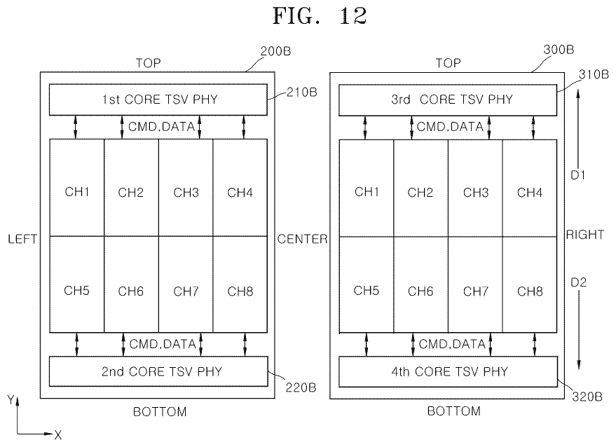

The second area 120B may include a first memory controller (1st MC) 121B-1, a first base interface area (1st DFI) 121B-2, a first base TSV area (1st TSV PHY) 121B-3, a second memory controller (2nd MC) 122B-1, a second base interface area (2nd DFI) 122B-2, and a second base TSV area (2nd TSV PHY) 122B-3 that control an operation of the first memory device 200B. The first memory controller 121B-1, the first base interface area 121B-2, and the first base TSV area 121B-3 may be components that control an operation of a first group of channels (CH1 to CH4 in FIG. 12) included in the first memory device 200B. The second memory controller 122B-1, the second base interface area 122B-2, and the second base TSV area 122B-3 may be components that control an operation of a second group of channels (CH5 to CH8 in FIG. 12) included in the first memory device 200B. Each of the first memory controller 121B-1, the first base interface area 121B-2, and the first base TSV area 121B-3 and the second memory controller 122B-1, the second base interface area 122B-2, and the second base TSV area 122B-3 may be the first memory controller 121B, the first base interface area 122B, and the first base TSV area 123B illustrated in FIG. 10.

The first memory controller 121B-1, the first base interface area 121B-2, and the first base TSV area 121B-3 may be arranged in the horizontal direction of the control device 100B. The second memory controller 122B-1, the second base interface area 122B-2, and the second base TSV area 122B-3 may be arranged in the horizontal direction of the control device 100B.

The first memory controller 121B-1 may be electrically connected to the first internal input and output line MIO1. The first memory controller 121B-1 may receive the command CMD and the data DATA that control an operation of the first group of channels (CH1 to CH4 in FIG. 12) included in the first memory device 200B through the first internal input and output line MIO1. The first memory controller 121B-1 may output the command CMD and the data DATA that control an operation of the first group of channels (CH1 to CH4 in FIG. 12) included in the first memory device 200B.

The first base interface area 121B-2 may be electrically connected to the first memory controller 121B-1. The first base interface area 121B-2 may receive the command CMD and the data DATA from the first memory controller 121B-1. The first base interface area 121B-2 may output the command CMD and the data DATA to the first base TSV area 121B-3 by adjusting the input and output sequence of the command CMD and the data DATA.

The first base TSV area 121B-3 may be electrically connected to the first base interface area 121B-2. The first base TSV area 121B-3 may receive the command CMD and the data DATA from the first base interface area 121B-2. The first base TSV area 121B-3 may output the command CMD and the data DATA to a first core TSV area (1st CORE TSV PHY) (210B in FIG. 12) included in the first memory device 200B through a plurality of TSVs.

The first memory controller 121B-1, the first base interface area 121B-2, and the first base TSV area 121B-3 may be sequentially disposed in a first direction D1 from the central area CENTER of the control device 100B. The first direction D1 may be set as a direction from the central area CENTER to a first edge area TOP. The first edge area TOP may be set as an upper area of the control device 100B in a Y axis. The first edge area TOP may be placed in an outward direction from the central area CENTER.

The second memory controller 122B-1 may be electrically connected to the second internal input and output line MIO2. The second memory controller 122B-1 may receive the command CMD and the data DATA that control an operation of the second group of channels (CH5 to CH8 in FIG. 12) included in the first memory device 200B through the second internal input and output line MIO2. The second memory controller 122B-1 may output the command CMD and the data DATA that control an operation of the second group of channels (CH5 to CH8 in FIG. 12) included in the first memory device 200B.

The second base interface area 122B-2 may be electrically connected to the second memory controller 122B-1. The second base interface area 122B-2 may receive the command CMD and the data DATA from the second memory controller 122B-1. The second base interface area 122B-2 may output the command CMD and the data DATA to the second base TSV area 122B-3 by adjusting the input and output sequence of the command CMD and the data DATA.

The second base TSV area 122B-3 may be electrically connected to the second base interface area 122B-2. The second base TSV area 122B-3 may receive the command CMD and the data DATA from the second base interface area 122B-2. The second base TSV area 122B-3 may output the command CMD and the data DATA to a second core TSV area (2nd CORE TSV PHY) (220B in FIG. 12) included in the first memory device 200B through a plurality of TSVs.

The second memory controller 122B-1, the second base interface area 122B-2, and the second base TSV area 122B-3 may be sequentially disposed in a second direction D2 from the central area CENTER of the control device 100B. The second direction D2 may be set as a direction from the central area CENTER to a second edge area BOTTOM. The second edge area BOTTOM may be set as a lower area of the control device 100B in the Y axis. The second edge area BOTTOM may be placed in an outward direction from the central area CENTER. The first edge area TOP and the second edge area BOTTOM may be placed in opposite directions from the central area CENTER.

The second area 120B may include a third memory controller (3rd MC) 123B-1, a third base interface area (3rd DFI) 123B-2, a third base TSV area (3rd TSV PHY) 123B-3, a fourth memory controller (4th MC) 124B-1, a fourth base interface area (4th DFI) 124B-2, and a fourth base TSV area (4th TSV PHY) 124B-3 that controls an operation of the second memory device 300B. The third memory controller 123B-1, the third base interface area 123B-2, and the third base TSV area 123B-3 may be components that control an operation of a first group of channels (CH1 to CH4 in FIG. 12) included in the second memory device 300B. The fourth memory controller 124B-1, the fourth base interface area 124B-2, and the fourth base TSV area 124B-3 may be components that control an operation of a second group of channels (CH5 to CH8 in FIG. 12) included in the second memory device 300B. Each of the third memory controller 123B-1, the third base interface area 123B-2, and the third base TSV area 123B-3, and the fourth memory controller 124BB-1, the fourth base interface area 124B-2, and the fourth base TSV area 124B-3 may be the second memory controller 125B, the second base interface area 126B, and the second base TSV area 127B illustrated in FIG. 10.

The third memory controller 123B-1, the third base interface area 123B-2, and the third base TSV area 123B-3 may be arranged in the horizontal direction of the control device 100B. The fourth memory controller 124B-1, the fourth base interface area 124B-2, and the fourth base TSV area 124B-3 may be arranged in the horizontal direction of the control device 100B.

The third memory controller 123B-1 may be electrically connected to the first internal input and output line MIO1. The third memory controller 123B-1 may receive the command CMD and the data DATA that control an operation of the first group of channels (CH1 to CH4 in FIG. 12) included in the second memory device 300B through the first internal input and output line MIO1. The third memory controller 123B-1 may output the command CMD and the data DATA that control an operation of the first group of channels (CH1 to CH4 in FIG. 12) included in the second memory device 300B.

The third base interface area 123B-2 may be electrically connected to the third memory controller 123B-1. The third base interface area 123B-2 may receive the command CMD and the data DATA from the third memory controller 123B-1. The third base interface area 123B-2 may output the command CMD and the data DATA to the third base TSV area 123B-3 by adjusting the input and output sequence of the command CMD and the data DATA.

The third base TSV area 123B-3 may be electrically connected to the third base interface area 123B-2. The third base TSV area 123B-3 may receive the command CMD and the data DATA from the third base interface area 123B-2. The third base TSV area 123B-3 may output the command CMD and the data DATA to a third core TSV area (3rd CORE TSV PHY) (310B in FIG. 12) included in the second memory device 300B through a plurality of TSVs.

The third memory controller 123B-1, the third base interface area 123B-2, and the third base TSV area 123B-3 may be sequentially disposed in the first direction D1 from the central area CENTER of the control device 100B.

The fourth memory controller 124B-1 may be electrically connected to the second internal input and output line MIO2. The fourth memory controller 124B-1 may receive the command CMD and the data DATA that control an operation of the second group of channels (CH5 to CH8 in FIG. 12) included in the second memory device 300B through the second internal input and output line MIO2. The fourth memory controller 124B-1 may output the command CMD and the data DATA that control an operation of the second group of channels (CH5 to CH8 in FIG. 12) included in the second memory device 300B.

The fourth base interface area 124B-2 may be electrically connected to the fourth memory controller 124B-1. The fourth base interface area 124B-2 may receive the command CMD and the data DATA from the fourth memory controller 124B-1. The fourth base interface area 124B-2 may output the command CMD and the data DATA to the fourth base TSV area 124B-3 by adjusting the input and output sequence of the command CMD and the data DATA.

The fourth base TSV area 124B-3 may be electrically connected to the fourth base interface area 124B-2. The fourth base TSV area 124B-3 may receive the command CMD and the data DATA from the fourth base interface area 124B-2. The fourth base TSV area 124B-3 may output the command CMD and the data DATA to a fourth core TSV area (4th CORE TSV PHY) (320B in FIG. 12) included in the second memory device 300 through a plurality of TSVs.

The fourth memory controller 124B-1, the fourth base interface area 124B-2, and the fourth base TSV area 124B-3 may be sequentially disposed in the second direction D2 from the central area CENTER of the control device 100B.

The second area 120B may be set as an area wherein the command CMD and the data DATA are received from the first area 110B and output to the first memory device 200B and the second memory device 300B. The second area 120B may be disposed in a right area RIGHT of the control device 100B in the X axis.

FIG. 12 illustrates the first memory device 200B and the second memory device 300B according to an embodiment of the present disclosure.

The first memory device 200B may include first to eighth channels CH1 to CH8, the first core TSV area 210B, and the second core TSV area 220B.

The first core TSV area 210B and the second core TSV area 220B may be arranged in the horizontal direction of the first memory device 200B.

The first to eighth channels CH1 to CH8 may receive the command CMD and the data DATA by independently performing internal operations. The first to eighth channels CH1 to CH8 may each store data DATA based on the command CMD after the start of a write operation of an internal operation. The first to eighth channels CH1 to CH8 may each output the data DATA based on the command CMD after the start of a read operation of an internal operation.

The first to fourth channels CH1 to CH4 may be electrically connected to the first core TSV area 210B. The first to fourth channels CH1 to CH4 may receive the command CMD and the data DATA from the first core TSV area 210B. The first to fourth channels CH1 to CH4 may output the data DATA to the first core TSV area 210B. The first to fourth channels CH1 to CH4 may each store data DATA based on the command CMD after the start of a write operation of an internal operation. The first to fourth channels CH1 to CH4 may each output the data DATA based on the command CMD after the start of a read operation of an internal operation. The first to fourth channels CH1 to CH4 may be set as the first group of channels.

The fifth to eighth channels CH5 to CH8 may be electrically connected to the second core TSV area 220B. The fifth to eighth channels CH5 to CH8 may receive a command CMD and data DATA from the second core TSV area 220B. The fifth to eighth channels CH5 to CH8 may output the data DATA to the second core TSV area 220B. The fifth to eighth channels CH5 to CH8 may each store data DATA based on the command CMD after the start of a write operation of an internal operation. The fifth to eighth channels CH5 to CH8 may each output the data DATA based on the command CMD after the start of a read operation of an internal operation. The first to fourth channels CH1 to CH4 may be set as the first group of channels. The fifth to eighth channels CH5 to CH8 may be set as the second group of channels.

The first to fourth channels CH1 to CH4 may be disposed in the central area CENTER of the first memory device 200B. The fifth to eighth channels CH5 to CH8 may be disposed in the central area CENTER of the first memory device 200B.

The first core TSV area 210B may be electrically connected to the first base TSV area 121B-3 of the control device 100B. The first core TSV area 210B may receive the command CMD and the data DATA from the first base TSV area 121B-3. The first core TSV area 210B may receive the command CMD and the data DATA through the plurality of TSVs. The first core TSV area 210B may output the command CMD and the data DATA to the first to fourth channels CH1 to CH4. The first core TSV area 210B may receive the data DATA from the first to fourth channels CH1 to CH4 and output the data DATA to the first base TSV area 121B-3. The first core TSV area 210B may be disposed in the first direction D1 from the central area CENTER. The first direction D1 may be set as a direction from the central area CENTER to the first edge area TOP. The first edge area TOP may be set as an upper area of the first memory device 200B in the Y axis. The first edge area TOP may be placed in an outward direction from the central area CENTER.

The second core TSV area 220B may be electrically connected to the second base TSV area 122B-3 of the control device 100B. The second core TSV area 220B may receive the command CMD and the data DATA from the second base TSV area 122B-3. The second core TSV area 220B may receive the command CMD and the data DATA through the plurality of TSVs. The second core TSV area 220B may output the command CMD and the data DATA to the fifth to eighth channels CH5 to CH8. The second core TSV area 220B may receive the data DATA from the fifth to eighth channels CH5 to CH8 and output the data DATA to the second base TSV area 122B-3. The second core TSV area 220B may be disposed in the second direction D2 from the central area CENTER. The second direction D2 may be set as a direction from the central area CENTER to the second edge area BOTTOM. The second edge area BOTTOM may be set as a lower area of the first memory device 200B in the Y axis. The second edge area BOTTOM may be placed in an outward direction from the central area CENTER. The first edge area TOP and the second edge area BOTTOM may be placed in opposite directions from the central area CENTER.

The first memory device 200B may be disposed in the left area LEFT of the X axis.

The second memory device 300B may include the first to eighth channels CH1 to CH8, the third core TSV area 310B, and the fourth core TSV area 320B.

The third core TSV area 310B and the fourth core TSV area 320B may be arranged in the horizontal direction of the second memory device 300B.

The first to eighth channels CH1 to CH8 may receive the command CMD and the data DATA by independently performing internal operations. The first to eighth channels CH1 to CH8 may each store data DATA based on the command CMD after the start of a write operation of an internal operation. The first to eighth channels CH1 to CH8 may each output the data DATA based on the command CMD after the start of a read operation of an internal operation.

The first to fourth channels CH1 to CH4 may be electrically connected to the third core TSV area 310B. The first to fourth channels CH1 to CH4 may receive the command CMD and the data DATA from the third core TSV area 310B. The first to fourth channels CH1 to CH4 may output the data DATA to the third core TSV area 310B. The first to fourth channels CH1 to CH4 may each store data DATA based on the command CMD after the start of a write operation of an internal operation. The first to fourth channels CH1 to CH4 may each output the data DATA based on the command CMD after the start of a read operation of an internal operation. The first to fourth channels CH1 to CH4 may be set as the first group of channels.

The fifth to eighth channels CH5 to CH8 may be electrically connected to the fourth core TSV area 320B. The fifth to eighth channels CH5 to CH8 may receive a command CMD and data DATA from the fourth core TSV area 320B. The fifth to eighth channels CH5 to CH8 may output the data DATA to the fourth core TSV area 320B. The fifth to eighth channels CH5 to CH8 may each store data DATA based on the command CMD after the start of a write operation of an internal operation. The fifth to eighth channels CH5 to CH8 may each output the data DATA based on the command CMD after the start of a read operation of an internal operation. The fifth to eighth channels CH5 to CH8 may be set as the second group of channels.

The first to eighth channels CH1 to CH8 may be disposed in the central area CENTER of the second memory device 300B.

The third core TSV area 310B may be electrically connected to the third base TSV area 123B-3 of the control device 100B. The third core TSV area 310B may receive the command CMD and the data DATA from the third base TSV area 123B-3. The third core TSV area 310B may receive the command CMD and the data DATA through the plurality of TSVs. The third core TSV area 310B may output the command CMD and the data DATA to the first to fourth channels CH1 to CH4. The third core TSV area 310B may receive the data DATA from the first to fourth channels CH1 to CH4 and output the data DATA to the third base TSV area 123B-3. The third core TSV area 310B may be disposed in the first direction D1 from the central area CENTER.

The fourth core TSV area 320B may be electrically connected to the fourth base TSV area 124B-3 of the control device 100B. The fourth core TSV area 320B may receive the command CMD and the data DATA from the fourth base TSV area 124B-3. The fourth core TSV area 320B may receive the command CMD and the data DATA through the plurality of TSVs. The fourth core TSV area 320B may output the command CMD and the data DATA to the fifth to eighth channels CH5 to CH8. The fourth core TSV area 320B may receive the data DATA from the fifth to eighth channels CH5 to CH8 and output the data DATA to the fourth base TSV area 124B-3. The fourth core TSV area 320B may be disposed in the second direction D2 from the central area CENTER.

The second memory device 300B may be disposed in the right area RIGHT of the X axis.

As described above, the semiconductor system 1B according to an embodiment of the present disclosure can increase the bandwidth because the first memory device 200B and the second memory device 300B are connected to the control device 100B in common and input and output the data DATA. In an embodiment, the semiconductor system 1B can prevent or reduce heat from an area in which the command CMD and the data DATA are generated from being diffused to a memory device because a memory device (e.g., 200B, 300B) is not stacked above the area in which the command CMD and the data DATA are generated.

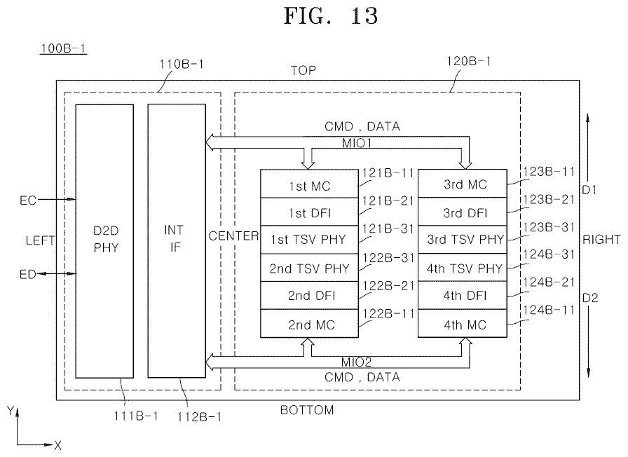

FIG. 13 illustrates a control device according to an embodiment of the present disclosure. In an embodiment, the control device 100B-1 represents the control device 100B illustrated in FIG. 10. As illustrated in FIG. 13, the control device 100B-1 may include a first area 110B-1 and a second area 120 B-1.

The first area 110B-1 may include a physical area (D2D PHY) 111B-1 and an internal interface area (INT IF) 112B-1.

The physical area 111B-1 may generate a command CMD based on an external command EC from an external device (e.g., the processor in FIG. 17). The physical area 111B-1 may generate the command CMD by buffering or decoding the external command EC. The external command EC and the command CMD each have been illustrated as one signal, but may each include a plurality of bits. The physical area 111B-1 may generate data DATA by receiving external data ED from an external device (e.g., the processor in FIG. 17). The physical area 111B-1 may generate the external data ED by receiving data DATA from the internal interface area 112B-1. The external data ED and the data DATA each have been illustrated as one signal, but may each include a plurality of bits.

The internal interface area 112B-1 may receive the command CMD and the data DATA from the physical area 111B-1. The internal interface area 112B-1 may output the command CMD and the data DATA to a first internal input and output line MIO1 by adjusting the input and output sequence of the command CMD and the data DATA that control operations of a first memory device 200B-1 and a second memory device 300B-1. The internal interface area 112B-1 may output the command CMD and the data DATA to a second internal input and output line MIO2 by adjusting the input and output sequence of the command CMD that controls operations of the first memory device 200B-1 and the second memory device 300B-1 and the data DATA. The first internal input and output line MIO1 may be disposed in a first edge area TOP of the control device 100B-1. The second internal input and output line MIO2 may be disposed in a second edge area BOTTOM of the control device 100B-1.

The first area 110B-1 may be set as an area in which the command CMD and the data DATA are generated. The first area 110B-1 may be set as an area in which heat is generated when the command CMD and the data DATA are generated. The first area 110B-1 may be disposed in a left area LEFT of the control device 100B-1 in an X axis.

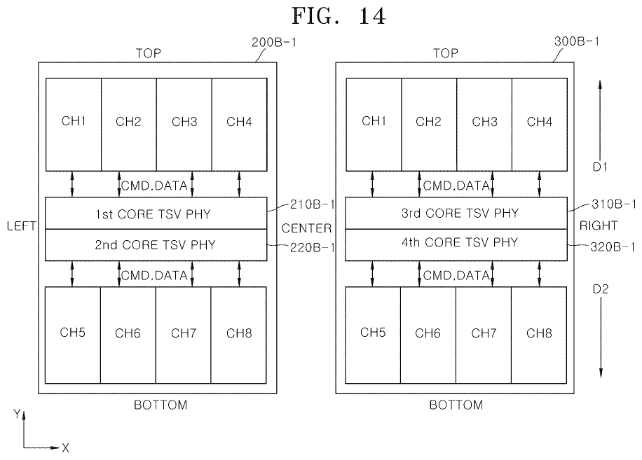

The second area 120B-1 may include a first memory controller (1st MC) 121B-11, a first base interface area (1st DFI) 121B-21, a first base TSV area (1st TSV PHY) 121B-31, a second memory controller (2nd MC) 122B-11, a second base interface area (2nd DFI) 122B-21, and a second base TSV area (2nd TSV PHY) 122B-31 that control an operation of the first memory device 200B-1. The first memory controller 121B-11, the first base interface area 121B-21, and the first base TSV area 121B-31 may be components that control an operation of a first group of channels (CH1 to CH4 in FIG. 14) included in the first memory device 200B-1. The second memory controller 122B-11, the second base interface area 122B-21, and the second base TSV area 122B-31 may be components that control an operation of a second group of channels (CH5 to CH8 in FIG. 14) included in the first memory device 200B-1.

The first memory controller 121B-11, the first base interface area 121B-21, and the first base TSV area 121B-31 may be arranged in the horizontal direction of the control device 100B-1. The second memory controller 122B-11, the second base interface area 122B-21, and the second base TSV area 122B-31 may be arranged in the horizontal direction of the control device 100B-1.

The first memory controller 121B-11 may be electrically connected to the first internal input and output line MIO1. The first memory controller 121B-11 may receive the command CMD and the data DATA that control an operation of the first group of channels (CH1 to CH4 in FIG. 14) included in the first memory device 200B-1 to the first internal input and output line MIO1. The first memory controller 121B-11 may output the command CMD and the data DATA that control an operation of the first group of channels (CH1 to CH4 in FIG. 14) included in the first memory device 200B-1.

The first base interface area 121B-21 may be electrically connected to the first memory controller 121B-11. The first base interface area 121B-21 may receive the command CMD and the data DATA from the first memory controller 121B-11. The first base interface area 121B-21 may output the command CMD and the data DATA to the first base TSV area 121B-31 by adjusting the input and output sequence of the command CMD and the data DATA.

The first base TSV area 121B-31 may be electrically connected to the first base interface area 121B-21. The first base TSV area 121B-31 may receive the command CMD and the data DATA from the first base interface area 121B-21. The first base TSV area 121B-31 may output the command CMD and the data DATA to a first core TSV area (1st CORE TSV PHY) (210B-1 in FIG. 14) included in the first memory device 200B-1 through a plurality of TSVs.

The first memory controller 121B-11, the first base interface area 121B-21, and the first base TSV area 121B-31 may be sequentially disposed in a second direction D2 from the first edge area TOP of the control device 100B-1. The second direction D2 may be set as a direction from the first edge area TOP to a central area CENTER. The first edge area TOP may be set as an upper area of the control device 100B-1 in a Y axis. The first edge area TOP may be placed in an outward direction from the central area CENTER.

The second memory controller 122B-11 may be electrically connected to the second internal input and output line MIO2. The second memory controller 122B-11 may receive the command CMD and the data DATA that control an operation of the second group of channels (CH5 to CH8 in FIG. 14) included in the first memory device 200B-1 through the second internal input and output line MIO2. The second memory controller 122B-11 may output the command CMD and the data DATA that control an operation of the second group of channels (CH5 to CH8 in FIG. 14) included in the first memory device 200B-1.

The second base interface area 122B-21 may be electrically connected to the second memory controller 122B-11. The second base interface area 122B-21 may receive the command CMD and the data DATA from the second memory controller 122B-11. The second base interface area 122B-21 may output the command CMD and the data DATA to the second base TSV area 122B-31 by adjusting the input and output sequence of the command CMD and the data DATA.

The second base TSV area 122B-31 may be electrically connected to the second base interface area 122B-21. The second base TSV area 122B-31 may receive the command CMD and the data DATA from the second base interface area 122B-21. The second base TSV area 122B-31 may output the command CMD and the data DATA to a second core TSV area (2nd CORE TSV PHY) (220B-1 in FIG. 14) included in the first memory device 200B-1 through a plurality of TSVs.

The second memory controller 122B-11, the second base interface area 122B-21, and the second base TSV area 122B-31 may be sequentially disposed in a first direction D1 from the second edge area BOTTOM of the control device 100B-1. The first direction D1 may be set as a direction from the second edge area BOTTOM to the central area CENTER. The second edge area BOTTOM may be set as a lower area of the control device 100B-1 in the Y axis. The second edge area BOTTOM may be placed in an outward direction from the central area CENTER. The first edge area TOP and the second edge area BOTTOM may be placed in opposite directions from the central area CENTER.

The second area 120B-1 may include a third memory controller (3rd MC) 123B-11, a third base interface area (3rd DFI) 123B-21, a third base TSV area (3rd TSV PHY) 123B-31, a fourth memory controller (4th MC) 124B-11, a fourth base interface area (4th DFI) 124B-21, and a fourth base TSV area (4th TSV PHY) 124B-31 that control an operation of the second memory device 300B-1. The third memory controller 123B-11, the third base interface area 123B-21, and the third base TSV area 123B-31 may be components that control an operation of a first group of channels (CH1 to CH4 in FIG. 14) included in the second memory device 300B-1. The fourth memory controller 124B-11, the fourth base interface area 124B-21, and the fourth base TSV area 124B-31 may be components that control an operation of a second group of channels (CH5 to CH8 in FIG. 14) included in the second memory device 300B-1.

The third memory controller 123B-11, the third base interface area 123B-21, and the third base TSV area 123B-31 may be arranged in the horizontal direction of the control device 100B-1. The fourth memory controller 124B-11, the fourth base interface area 124B-21, and the fourth base TSV area 124B-31 may be arranged in the horizontal direction of the control device 100B-1.

The third memory controller 123B-11 may be electrically connected to the first internal input and output line MIO1. The third memory controller 123B-11 may receive the command CMD and the data DATA that control an operation of the first group of channels (CH1 to CH4 in FIG. 14) included in the second memory device 300B-1 through the first internal input and output line MIO1. The third memory controller 123B-11 may output the command CMD and the data DATA that control an operation of the first group of channels (CH1 to CH4 in FIG. 14) included in the second memory device 300B-1.

The third base interface area 123B-21 may be electrically connected to the third memory controller 123B-11. The third base interface area 123B-21 may receive the command CMD and the data DATA from the third memory controller 123B-11. The third base interface area 123B-21 may output the command CMD and the data DATA to the third base TSV area 123B-31 by adjusting the input and output sequence of the command CMD and the data DATA.

The third base TSV area 123B-31 may be electrically connected to the third base interface area 123B-21. The third base TSV area 123B-31 may receive the command CMD and the data DATA from the third base interface area 123B-21. The third base TSV area 123B-31 may output the command CMD and the data DATA to a third core TSV area (3rd CORE TSV PHY) (310B-1 in FIG. 14) included in the second memory device 300B-1 through a plurality of TSVs.

The third memory controller 123B-11, the third base interface area 123B-21, and the third base TSV area 123B-31 may be sequentially disposed in the second direction D2 from the first edge area TOP of the control device 100A.

The fourth memory controller 124B-11 may be electrically connected to the second internal input and output line MIO2. The fourth memory controller 124B-11 may receive the command CMD and the data DATA through that control an operation of the second group of channels (CH5 to CH8 in FIG. 14) included in the second memory device 300B-1 the second internal input and output line MIO2. The fourth memory controller 124B-11 may output the command CMD and the data DATA that control an operation of the second group of channels (CH5 to CH8 in FIG. 14) included in the second memory device 300B-1.

The fourth base interface area 124B-21 may be electrically connected to the fourth memory controller 124B-11. The fourth base interface area 124B-21 may receive the command CMD and the data DATA from the fourth memory controller 124B-11. The fourth base interface area 124B-21 may output the command CMD and the data DATA to the fourth base TSV area 124B-31 by adjusting the input and output sequence of the command CMD and the data DATA.

The fourth base TSV area 124B-31 may be electrically connected to the fourth base interface area 124B-21. The fourth base TSV area 124B-31 may receive the command CMD and the data DATA from the fourth base interface area 124B-21. The fourth base TSV area 124B-31 may output the command CMD and the data DATA to a fourth core TSV area (4th CORE TSV PHY) (320B-1 in FIG. 14) included in the second memory device 300B-1 through a plurality of TSVs.

The fourth memory controller 124B-11, the fourth base interface area 124B-21, and the fourth base TSV area 124B-31 may be sequentially disposed in the first direction D1 from the second edge area BOTTOM of the control device 100B-1.

The second area 120B-1 may be set as an area in which the command CMD and the data DATA are received from the first area 110B-1 and output to the first memory device 200B-1 and the second memory device 300B-1. The second area 120B-1 may be disposed in a right area RIGHT in the X axis of the control device 100B-1.

FIG. 14 illustrates the first memory device 200B-1 and the second memory device 300B-1 according to an embodiment of the present disclosure.

The first memory device 200B-1 may include the first to eighth channels CH1 to CH8, the first core TSV area 210B-1, and the second core TSV area 220B-1.

The first core TSV area 210B-1 and the second core TSV area 220B-1 may be arranged in the horizontal direction of the first memory device 200B-1.

The first to eighth channels CH1 to CH8 may receive the command CMD and the data DATA by independently performing internal operations. The first to eighth channels CH1 to CH8 may each store data DATA based on the command CMD after the start of a write operation of an internal operation. The first to eighth channels CH1 to CH8 may each output the data DATA based on the command CMD after the start of a read operation of an internal operation.

The first to fourth channels CH1 to CH4 may be electrically connected to the first core TSV area 210B-1. The first to fourth channels CH1 to CH4 may receive the command CMD and the data DATA from the first core TSV area 210B-1. The first to fourth channels CH1 to CH4 may output the data DATA to the first core TSV area 210B-1. The first to fourth channels CH1 to CH4 may each store data DATA based on the command CMD after the start of a write operation of an internal operation. The first to fourth channels CH1 to CH4 may each output the data DATA based on the command CMD after the start of a read operation of an internal operation. The first to fourth channels CH1 to CH4 may be set as the first group of channels.

The fifth to eighth channels CH5 to CH8 may be electrically connected to the second core TSV area 220B-1. The fifth to eighth channels CH5 to CH8 may receive a command CMD and data DATA from the second core TSV area 220B-1. The fifth to eighth channels CH5 to CH8 may output the data DATA to the second core TSV area 220B-1. The fifth to eighth channels CH5 to CH8 may each store data DATA based on the command CMD after the start of a write operation of an internal operation. The fifth to eighth channels CH5 to CH8 may each output the data DATA based on the command CMD after the start of a read operation of an internal operation. The fifth to eighth channels CH5 to CH8 may be set as the second group of channels.

The first to fourth channels CH1 to CH4 may be disposed in the first edge area TOP of the first memory device 200B-1. The fifth to eighth channels CH5 to CH8 may be disposed in the second edge area BOTTOM of the first memory device 200B-1.

The first core TSV area 210B-1 may be electrically connected to the first base TSV area 121B-31 of the control device 100B-1. The first core TSV area 210B-1 may receive the command CMD and the data DATA from the first base TSV area 121B-31. The first core TSV area 210B-1 may receive the command CMD and the data DATA through the plurality of TSVs. The first core TSV area 210B-1 may output the command CMD and the data DATA to the first to fourth channels CH1 to CH4. The first core TSV area 210B-1 may receive the data DATA from the first to fourth channels CH1 to CH4 and output the data DATA to the first base TSV area 121B-31. The first core TSV area 210B-1 may be disposed in the central area CENTER. The first core TSV area 210B-1 may be disposed in the second direction D2 from the first edge area TOP. The second direction D2 may be set as a direction from the first edge area TOP to the central area CENTER. The first edge area TOP may be set as an upper area of the first memory device 200B-1 in the Y axis. The first edge area TOP may be placed in an outward direction from the central area CENTER.

The second core TSV area 220B-1 may be electrically connected to the second base TSV area 122B-31 of the control device 100B-1. The second core TSV area 220B-1 may receive the command CMD and the data DATA from the second base TSV area 122B-31. The second core TSV area 220B-1 may receive the command CMD and the data DATA through the plurality of TSVs. The second core TSV area 220B-1 may output the command CMD and the data DATA to the fifth to eighth channels CH5 to CH8. The second core TSV area 220B-1 may receive the data DATA from the fifth to eighth channels CH5 to CH8 and output the data DATA to the second base TSV area 122B-31. The second core TSV area 220B-1 may be disposed in the central area CENTER. The second core TSV area 220B-1 may be disposed in the first direction D1 from the second edge area BOTTOM. The first direction D1 may be set as a direction from the second edge area BOTTOM to the central area CENTER. The second edge area BOTTOM may be set as a lower area of the first memory device 200B-1 in the Y axis. The second edge area BOTTOM may be placed in an outward direction from the central area CENTER. The first edge area TOP and the second edge area BOTTOM may be placed in opposite directions from the central area CENTER.

The first memory device 200B-1 may be disposed in the left area LEFT of the X axis.

The second memory device 300B-1 may include the first to eighth channels CH1 to CH8, the third core TSV area 310B-1, and the fourth core TSV area 320B-1.

The third core TSV area 310B-1 and the fourth core TSV area 320B-1 may be arranged in the horizontal direction of the second memory device 300B-1.

The first to eighth channels CH1 to CH8 may receive the command CMD and the data DATA by independently performing internal operations. The first to eighth channels CH1 to CH8 may each store data DATA based on the command CMD after the start of a write operation of an internal operation. The first to eighth channels CH1 to CH8 may each output the data DATA based on the command CMD after the start of a read operation of an internal operation.

The first to fourth channels CH1 to CH4 may be electrically connected to the third core TSV area 310B-1. The first to fourth channels CH1 to CH4 may receive the command CMD and the data DATA from the third core TSV area 310B-1. The first to fourth channels CH1 to CH4 may output the data DATA to the third core TSV area 310B-1. The first to fourth channels CH1 to CH4 may each store data DATA based on the command CMD after the start of a write operation of an internal operation. The first to fourth channels CH1 to CH4 may each output the data DATA based on the command CMD after the start of a read operation of an internal operation. The first to fourth channels CH1 to CH4 may be set as the first group of channels.

The fifth to eighth channels CH5 to CH8 may be electrically connected to the fourth core TSV area 320B-1. The fifth to eighth channels CH5 to CH8 may receive a command CMD and data DATA from the fourth core TSV area 320B-1. The fifth to eighth channels CH5 to CH8 may output the data DATA to the fourth core TSV area 320B-1. The fifth to eighth channels CH5 to CH8 may each store data DATA based on the command CMD after the start of a write operation of an internal operation. The fifth to eighth channels CH5 to CH8 may each output the data DATA based on the command CMD after the start of a read operation of an internal operation. The fifth to eighth channels CH5 to CH8 may be set as the second group of channels.

The first to eighth channels CH1 to CH8 may be disposed in the first edge area TOP of the second memory device 300B-1.

The third core TSV area 310B-1 may be electrically connected to the third base TSV area 123B-31 of the control device 100B-1. The third core TSV area 310B-1 may receive the command CMD and the data DATA from the third base TSV area 123B-31. The third core TSV area 310B-1 may receive the command CMD and the data DATA through the plurality of TSVs. The third core TSV area 310B-1 may output the command CMD and the data DATA to the first to fourth channels CH1 to CH4. The third core TSV area 310B-1 may receive the data DATA from the first to fourth channels CH1 to CH4 and output the data DATA to the third base TSV area 123B-31. The third core TSV area 310B-1 may be disposed in the central area CENTER. The third core TSV area 310B-1 may be disposed in the second direction D2 from the first edge area TOP.

The fourth core TSV area 320B-1 may be electrically connected to the fourth base TSV area 124B-31 of the control device 100B-1. The fourth core TSV area 320B-1 may receive the command CMD and the data DATA from the fourth base TSV area 124B-31. The fourth core TSV area 320B-1 may receive the command CMD and the data DATA through the plurality of TSVs. The fourth core TSV area 320B-1 may output the command CMD and the data DATA to the fifth to eighth channels CH5 to CH8. The fourth core TSV area 320B-1 may receive the data DATA from the fifth to eighth channels CH5 to CH8 and output the data DATA to the fourth base TSV area 124B-31. The fourth core TSV area 320B-1 may be disposed in the central area CENTER. The fourth core TSV area 320B-1 may be disposed in the first direction D1 from the second edge area BOTTOM.

The second memory device 300B-1 may be disposed in the right area RIGHT of the X axis.

As described above, the semiconductor system 1B according to an embodiment of the present disclosure can increase the bandwidth because the first memory device 200B-1 and the second memory device 300B-1 are connected to the control device 100B-1 in common and input and output the data DATA. In an embodiment, the semiconductor system 1B can prevent or reduce heat from an area in which the command CMD and the data DATA are generated from being diffused to a memory device because a memory device (e.g., 200B-1, 300B-1) is not stacked above the area in which the command CMD and the data DATA are generated.

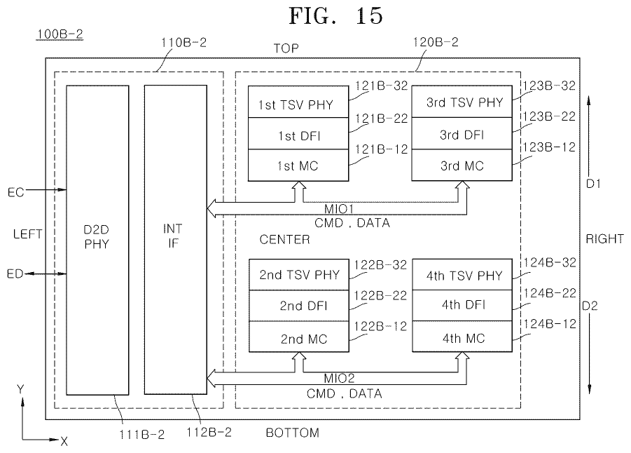

FIG. 15 illustrates the control device 100B according to an embodiment of the present disclosure. As illustrated in FIG. 15, a control device 100B-2 may include a first area 110B-2 and a second area 120B-2.

The first area 110B-2 may include a physical area (D2D PHY) 111B-2 and an internal interface area (INT IF) 112B-2.

The physical area 111B-2 may generate the command CMD based on an external command EC from an external device (e.g., the processor in FIG. 17). The physical area 111B-2 may generate the command CMD by buffering or decoding the external command EC. The external command EC and the command CMD each have been illustrated as one signal, but may each include a plurality of bits. The physical area 111B-2 may generate the data DATA by receiving external data ED from an external device (e.g., the processor in FIG. 17). The physical area 111B-2 may generate the external data ED by receiving data DATA from the internal interface area 112B-2. The physical area 111B-2 may output the external data ED to an external device (e.g., the processor in FIG. 17). The external data ED and the data DATA each have been illustrated as one signal, but may each include a plurality of bits.

The internal interface area 112B-2 may receive the command CMD and the data DATA from the physical area 111B-2. The internal interface area 112B-2 may output the command CMD and the data DATA to a first internal input and output line MIO1 by adjusting the input and output sequence of the command CMD and the data DATA that control operations of a first memory device 200B-2 and a second memory device 300B-2. The internal interface area 112B-2 may output the command CMD and the data DATA to a second internal input and output line MIO2 by adjusting the input and output sequence of the command CMD and the data DATA that control operations of the first memory device 200B-2 and the second memory device 300B-2. The first internal input and output line MIO1 may be disposed in a central area CENTER of the control device 100B-2. The second internal input and output line MIO2 may be disposed in a second edge area BOTTOM of the control device 100B-2.

The first area 110B-2 may be set as an area in which the command CMD and the data DATA are generated. The first area 110B-2 may be set as an area in which heat is generated when the command CMD and the data DATA are generated. The first area 110B-2 may be disposed in a left area LEFT of the control device 100B-2 in an X axis.

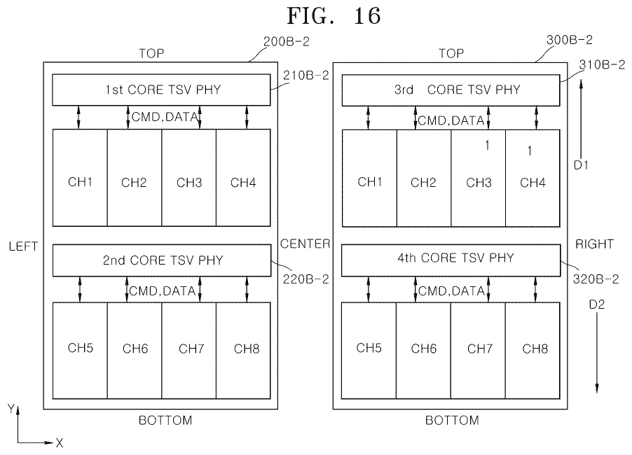

The second area 120B-2 may include a first memory controller (1st MC) 121B-12, a first base interface area (1st DFI) 121B-22, a first base TSV area (1st TSV PHY) 121B-32, a second memory controller (2nd MC) 122B-12, a second base interface area (2nd DFI) 122B-22, and a second base TSV area (2nd TSV PHY) 122B-32 that control an operations of the first memory device 200B-2. The first memory controller 121B-12, the first base interface area 121B-22, and the first base TSV area 121B-32 may be components that control an operation of a first group of channels (CH1 to CH4 in FIG. 16) included in the first memory device 200B-2. The second memory controller 122B-12, the second base interface area 122B-22, and the second base TSV area 122B-32 may be components that control an operation of a second group of channels (CH5 to CH8 in FIG. 16) included in the first memory device 200B-2.

The first memory controller 121B-12, the first base interface area 121B-22, and the first base TSV area 121B-32 may be arranged in the horizontal direction of the control device 100B-2. The second memory controller 122B-12, the second base interface area 122B-22, and a second base TSV area 122B-32 may be arranged in the horizontal direction of the control device 100B-2.

The first memory controller 121B-12 may be electrically connected to the first internal input and output line MIO1. The first memory controller 121B-12 may receive the command CMD and the data DATA that control an operation of the first group of channels (CH1 to CH4 in FIG. 16) included in the first memory device 200B-2 through the first internal input and output line MIO1. The first memory controller 121B-12 may output the command CMD and the data DATA that control an operation of the first group of channels (CH1 to CH4 in FIG. 16) included in the first memory device 200B-2.

The first base interface area 121B-22 may be electrically connected to the first memory controller 121B-12. The first base interface area 121B-22 may receive the command CMD and the data DATA from the first memory controller 121B-12. The first base interface area 121B-22 may output the command CMD and the data DATA to the first base TSV area 121B-32 by adjusting the input and output sequence of the command CMD and the data DATA.

The first base TSV area 121B-32 may be electrically connected to the first base interface area 121B-22. The first base TSV area 121B-32 may receive the command CMD and the data DATA from the first base interface area 121B-22. The first base TSV area 121B-32 may output the command CMD and the data DATA to a first core TSV area (1st CORE TSV PHY) (210B-2 in FIG. 16) included in the first memory device 200B-2 through a plurality of TSVs.

The first memory controller 121B-12, the first base interface area 121B-22, and the first base TSV area 121B-32 may be sequentially disposed in a first direction D1 from the central area CENTER of the control device 100B-2. The first direction D1 may be set as a direction from the central area CENTER to a first edge area TOP. The first edge area TOP may be set as an upper area of the control device 100B-2 in a Y axis. The first edge area TOP may be placed in an outward direction from the central area CENTER.

The second memory controller 122B-12 may be electrically connected to the second internal input and output line MIO2. The second memory controller 122B-12 may receive the command CMD and the data DATA that control an operation of the second group of channels (CH5 to CH8 in FIG. 16) included in the first memory device 200B-2 through the second internal input and output line MIO2. The second memory controller 122B-12 may output the command CMD and the data DATA that control an operation of the second group of channels (CH5 to CH8 in FIG. 16) included in the first memory device 200B-2.

The second base interface area 122B-22 may be electrically connected to the second memory controller 122B-12. The second base interface area 122B-22 may receive the command CMD and the data DATA from the second memory controller 122B-12. The second base interface area 122B-22 may output the command CMD and the data DATA to the second base TSV area 122B-32 by adjusting the input and output sequence of the command CMD and the data DATA.

The second base TSV area 122B-32 may be electrically connected to the second base interface area 122B-22. The second base TSV area 122B-32 may receive the command CMD and the data DATA from the second base interface area 122B-22. The second base TSV area 122B-32 may output the command CMD and the data DATA to a second core TSV area (2nd CORE TSV PHY) (220B-2 in FIG. 16) included in the first memory device 200B-2 through a plurality of TSVs.

The second memory controller 122B-12, the second base interface area 122B-22, and the second base TSV area 122B-32 may be sequentially disposed in the first direction D1 from the second edge area BOTTOM of the control device 100B-2. The first direction D1 may be set as a direction from the second edge area BOTTOM to the central area CENTER. The second edge area BOTTOM may be set as a lower area of the control device 100B-2 in the Y axis. The second edge area BOTTOM may be placed in an outward direction from the central area CENTER. The first edge area TOP and the second edge area BOTTOM may be placed in opposite directions from the central area CENTER.

The second area 120B-2 may include a third memory controller (3rd MC) 123B-12, a third base interface area (3rd DFI) 123B-22, a third base TSV area (3rd TSV PHY) 123B-32, a fourth memory controller (4th MC) 124B-12, a fourth base interface area (4th DFI) 124B-22, and a fourth base TSV area (4th TSV PHY) 124B-32 that control an operation of the second memory device 300B-2. The third memory controller 123B-12, the third base interface area 123B-22 and the third base TSV area 123B-32 may be components that control an operation of a first group of channels (CH1 to CH4 in FIG. 16) included in the second memory device 300B-2. The fourth memory controller 124B-12, the fourth base interface area 124B-22, and the fourth base TSV area 124B-32 may be components that control an operation of a second group of channels (CH5 to CH8 in FIG. 16) included in the second memory device 300B-2.

The third memory controller 123B-12, the third base interface area 123B-22, and the third base TSV area 123B-32 may be arranged in the horizontal direction of the control device 100B-2. The fourth memory controller 124B-12, the fourth base interface area 124B-22, and the fourth base TSV area 124B-32 may be arranged in the horizontal direction of the control device 100B-2.

The third memory controller 123B-12 may be electrically connected to the first internal input and output line MIO1. The third memory controller 123B-12 may receive the command CMD and the data DATA that control an operation of the first group of channels (CH1 to CH4 in FIG. 16) included in the second memory device 300B-2 through the first internal input and output line MIO1. The third memory controller 123B-12 may output the command CMD and the data DATA that control an operation of the first group of channels (CH1 to CH4 in FIG. 16) included in the second memory device 300B-2.

The third base interface area 123B-22 may be electrically connected to the third memory controller 123B-12. The third base interface area 123B-22 may receive the command CMD and the data DATA from the third memory controller 123B-12. The third base interface area 123B-22 may output the command CMD and the data DATA to the third base TSV area 123B-32 by adjusting the input and output sequence of the command CMD and the data DATA.

The third base TSV area 123B-32 may be electrically connected to the third base interface area 123B-22. The third base TSV area 123B-32 may receive the command CMD and the data DATA from the third base interface area 123B-22. The third base TSV area 123B-32 may output the command CMD and the data DATA to a third core TSV area (3rd CORE TSV PHY) (310B-2 in FIG. 16) included in the second memory device 300B-2 through a plurality of TSVs.

The third memory controller 123B-12, the third base interface area 123B-22, and the third base TSV area 123B-32 may be sequentially disposed in the first direction D1 from the central area CENTER of the control device 100B-2.

The fourth memory controller 124B-12 may be electrically connected to the second internal input and output line MIO2. The fourth memory controller 124B-12 may receive the command CMD and the data DATA that control an operation of the second group of channels (CH5 to CH8 in FIG. 16) included in the second memory device 300B-2 through the second internal input and output line MIO2. The fourth memory controller 124B-12 may output the command CMD and the data DATA that control an operation of the second group of channels (CH5 to CH8 in FIG. 16) included in the second memory device 300B-2.

The fourth base interface area 124B-22 may be electrically connected to the fourth memory controller 124B-12. The fourth base interface area 124B-22 may receive the command CMD and the data DATA from the fourth memory controller 124B-12. The fourth base interface area 124B-22 may output the command CMD and the data DATA to the fourth base TSV area 124B-32 by adjusting the input and output sequence of the command CMD and the data DATA.

The fourth base TSV area 124B-32 may be electrically connected to the fourth base interface area 124B-22. The fourth base TSV area 124B-32 may receive the command CMD and the data DATA from the fourth base interface area 124B-22. The fourth base TSV area 124B-32 may output the command CMD and the data DATA to a fourth core TSV area (4th CORE TSV PHY) (320B-2 in FIG. 16) included in the second memory device 300B-2 through a plurality of TSVs.

The fourth memory controller 124B-12, the fourth base interface area 124B-22, and the fourth base TSV area 124B-32 may be sequentially disposed in the first direction D1 from the second edge area BOTTOM of the control device 100B-2.

The second area 120B-2 may be set as an area in which the command CMD and the data DATA are received from the first area 110B-2 and output to the first memory device 200B-2 and the second memory device 300B-2. The second area 120B-2 may be disposed in a right area RIGHT of the control device 100B-2 in the X axis.

FIG. 16 illustrates the first memory device 200B-2 and the second memory device 300B-2 according to an embodiment of the present disclosure.

The first memory device 200B-2 may include the first to eighth channels CH1 to CH8, the first core TSV area 210B-2, and the second core TSV area 220B-2.

The first core TSV area 210B-2, and the second core TSV area 220B-2 may be arranged in the horizontal direction of the first memory device 200B-2.

The first to eighth channels CH1 to CH8 may receive the command CMD and the data DATA by independently performing internal operations. The first to eighth channels CH1 to CH8 may each store data DATA based on the command CMD after the start of a write operation of an internal operation. The first to eighth channels CH1 to CH8 may each output the data DATA based on the command CMD after the start of a read operation of an internal operation.

The first to fourth channels CH1 to CH4 may be electrically connected to the first core TSV area 210B-2. The first to fourth channels CH1 to CH4 may receive the command CMD and the data DATA from the first core TSV area 210B-2. The first to fourth channels CH1 to CH4 may output the data DATA to the first core TSV area 210B-2. The first to fourth channels CH1 to CH4 may each store data DATA based on the command CMD after the start of a write operation of an internal operation. The first to fourth channels CH1 to CH4 may each output the data DATA based on the command CMD after the start of a read operation of an internal operation. The first to fourth channels CH1 to CH4 may be set as the first group of channels.

The fifth to eighth channels CH5 to CH8 may be electrically connected to the second core TSV area 220B-2. The fifth to eighth channels CH5 to CH8 may receive a command CMD and data DATA from the second core TSV area 220B-2. The fifth to eighth channels CH5 to CH8 may output the data DATA to the second core TSV area 220B-2. The fifth to eighth channels CH5 to CH8 may each store data DATA based on the command CMD after the start of a write operation of an internal operation. The fifth to eighth channels CH5 to CH8 may each output the data DATA based on the command CMD after the start of a read operation of an internal operation. The fifth to eighth channels CH5 to CH8 may be set as the second group of channels.

The first to fourth channels CH1 to CH4 may be disposed in a central area CENTER of the first memory device 200B-2. The fifth to eighth channels CH5 to CH8 may be disposed in a second edge area BOTTOM of the first memory device 200B-2.

The first core TSV area 210B-2 may be electrically connected to the first base TSV area 121B-32 of the control device 100B-2. The first core TSV area 210B-2 may receive the command CMD and the data DATA from the first base TSV area 121B-32. The first core TSV area 210B-2 may receive the command CMD and the data DATA through a plurality of TSVs. The first core TSV area 210B-2 may output the command CMD and the data DATA to the first to fourth channels CH1 to CH4. The first core TSV area 210B-2 may receive the data DATA from the first to fourth channels CH1 to CH4 and output the data DATA to the first base TSV area 121B-32. The first core TSV area 210B-2 may be disposed in a first direction D1 from the central area CENTER. The first direction D1 may be set as a direction from the central area CENTER to a first edge area TOP. The first edge area TOP may be set as an upper area of the first memory device 200B-2 in the Y axis. The first edge area TOP may be placed in an outward direction from the central area CENTER.

The second core TSV area 220B-2 may be electrically connected to the second base TSV area 122B-32 of the control device 100B-2. The second core TSV area 220B-2 may receive the command CMD and the data DATA from the second base TSV area 122B-32. The second core TSV area 220B-2 may receive the command CMD and the data DATA through the plurality of TSVs. The second core TSV area 220B-2 may output the command CMD and the data DATA to the fifth to eighth channels CH5 to CH8. The second core TSV area 220B-2 may receive the data DATA from the fifth to eighth channels CH5 to CH8 and output the data DATA to the second base TSV area 122B-32. The second core TSV area 220B-2 may be disposed in the central area CENTER. The second core TSV area 220B-2 may be disposed in the first direction D1 from the second edge area BOTTOM. The first direction D1 may be set as a direction from the second edge area BOTTOM to the central area CENTER. The second edge area BOTTOM may be set as a lower area of the first memory device 200B-2 in a Y axis. The second edge area BOTTOM may be placed in an outward direction from the central area CENTER. The first edge area TOP and the second edge area BOTTOM may be placed in opposite directions from the central area CENTER.

The first memory device 200B-2 may be disposed of in a left area LEFT of the first memory device 200B-2 in an X axis.

The second memory device 300B-2 may include the first to eighth channels CH1 to CH8, the third core TSV area 310B-2, and the fourth core TSV area 320B-2.

The third core TSV area 310B-2, and the fourth core TSV area 320B-2 may be arranged in the horizontal direction of the second memory device 300B-2.

The first to eighth channels CH1 to CH8 may receive the command CMD and the data DATA by independently performing internal operations. The first to eighth channels CH1 to CH8 may each store data DATA based on the command CMD after the start of a write operation of an internal operation. The first to eighth channels CH1 to CH8 may each output the data DATA based on the command CMD after the start of a read operation of an internal operation.

The first to fourth channels CH1 to CH4 may be electrically connected to the third core TSV area 310B-2. The first to fourth channels CH1 to CH4 may receive the command CMD and the data DATA from the third core TSV area 310B-2. The first to fourth channels CH1 to CH4 may output the data DATA to the third core TSV area 310B-2. The first to fourth channels CH1 to CH4 may each store data DATA based on the command CMD after the start of a write operation of an internal operation. The first to fourth channels CH1 to CH4 may each output the data DATA based on the command CMD after the start of a read operation of an internal operation. The first to fourth channels CH1 to CH4 may be set as the first group of channels.

The fifth to eighth channels CH5 to CH8 may be electrically connected to the fourth core TSV area 320B-2. The fifth to eighth channels CH5 to CH8 may receive a command CMD and data DATA from the fourth core TSV area 320B-2. The fifth to eighth channels CH5 to CH8 may output the data DATA to the fourth core TSV area 320B-2. The fifth to eighth channels CH5 to CH8 may each store data DATA based on the command CMD after the start of a write operation of an internal operation. The fifth to eighth channels CH5 to CH8 may each output the data DATA based on the command CMD after the start of a read operation of an internal operation. The fifth to eighth channels CH5 to CH8 may be set as the second group of channels.

The first to fourth channels CH1 to CH4 may be disposed in the central area CENTER of the second memory device 300B-2. The fifth to eighth channels CH5 to CH8 may be disposed in the second edge area BOTTOM of the second memory device 300B-2.

The third core TSV area 310B-2 may be electrically connected to the third base TSV area 123B-32 of the control device 100B-2. The third core TSV area 310B-2 may receive the command CMD and the data DATA from the third base TSV area 123B-32. The third core TSV area 310B-2 may receive the command CMD and the data DATA through a plurality of TSVs. The third core TSV area 310B-2 may output the command CMD and the data DATA to the first to fourth channels CH1 to CH4. The third core TSV area 310B-2 may receive the data DATA from the first to fourth channels CH1 to CH4 and output the data DATA to the third base TSV area 123B-32. The third core TSV area 310B-2 may be disposed in the first edge area TOP. The third core TSV area 310B-2 may be disposed in the first direction D1 from the central

### Area Center.

The fourth core TSV area 320B-2 may be electrically connected to the fourth base TSV area 124B-31 of the control device 100B-2. The fourth core TSV area 320B-2 may receive the command CMD and the data DATA from the fourth base TSV area 124B-32. The fourth core TSV area 320B-2 may receive the command CMD and the data DATA through a plurality of TSVs. The fourth core TSV area 320B-2 may output the command CMD and the data DATA to the fifth to eighth channels CH5 to CH8. The fourth core TSV area 320B-2 may receive the data DATA from the fifth to eighth channels CH5 to CH8 and output the data DATA to the fourth base TSV area 124B-32. The fourth core TSV area 320B-2 may be disposed in the central area CENTER. The fourth core TSV area 320B-2 may be disposed in the first direction D1 from the second edge area BOTTOM.

The second memory device 300B-2 may be disposed in the right area RIGHT in the X axis.

As described above, the semiconductor system 1B according to an embodiment of the present disclosure can increase the bandwidth because the first memory device 200B-2 and the second memory device 300B-2 are connected to the control device 100B-2 in common and input and output the data DATA. In an embodiment, the semiconductor system 1B can prevent or reduce heat from an area in which the command CMD and the data DATA are generated from being diffused to a memory device because a memory device (i.e., 200B-2, 300B-2) is not stacked above the area in which the command CMD and the data DATA are generated. Interfaces that are connected to the TSVs of the control device 100B, 100B-1, 100B-2 and the memory devices 200B, 200B-1, 200B-2, 300B, 300B-1, 300B-2 may be variously disposed in the semiconductor system 1B.

FIG. 17 illustrates a semiconductor device 3B according to an embodiment of the present disclosure. As illustrated in FIG. 17, the semiconductor device 3B may include a PCB 11B, a substrate 13B, an interposer 15B, an HBM device 17B, and the processor 19B.

The PCB 11B connects several electronic components in order to form an electronic circuit (not illustrated). A copper layer, a solder mask and a silk screen may be formed on the PCB 11B. A circuit path that transmits a signal or power may be formed in the copper layer. In an embodiment, the solder mask prevents or mitigates damage to the circuit and protects a specific area in which components may be soldered. Furthermore, in an embodiment, the silk screen indicates a position or information of an electronic component in the form of characters or symbols printed on a surface of the PCB 11B.

The substrate 13B is formed over the PCB 11B through bump pads (e.g., 115B), and may mechanically support the interposer 15B, the HBM device 17B, and the processor 19B. The substrate 13B may be used as an insulator as a material, that is, a physical base for the PCB 11B, in general. The material of the substrate 13B include FR4, that is, an insulator made of glass fiber and epoxy resin, ceramics that can withstand a high temperature and can be used in a high frequency circuit or a high temperature environment due to its thermal conductivity, and polyimide that is used as a base material for a flexible PCB due to its flexible characteristic.

The interposer 15B is formed over the substrate 13B through bump pads, and may include wires that connect electronic components (e.g., the HBM device 17B and the processor 19B) with unmatched foam factors or pin arrangements. The interposer 15B may convert signals in different interfaces.

The HBM device 17B may be formed over the interposer 15B to micro bump pads (e.g., 117B). The HBM device 17B may store data applied by the processor 19B or output data stored in the HBM device 17B to the processor 19B, under the control of the processor 19B. The HBM device 17B may include a control device 150B, a first memory device 160B, and a second memory device 170B. The first memory device 160B and the second memory device 170B may be stacked on the control device 150B through micro bump pads. The first memory device 160B and the second memory device 170B may each be implemented with a plurality of core chips that is vertically stacked through micro bump pads. The control device 150B and the first memory device 160B and the second memory device 170B may be vertically stacked through TSVs.

The control device 150B may generate the command CMD by receiving the external command EC from the processor 19B, and may generate the data DATA by receiving the external data ED from the processor 19B. The control device 150B may include the first area (110B, 110B-1, and 110B-2 illustrated in FIGS. 1, 2, 4, and 6) in which the command CMD and the data DATA are generated. The first area may be set as an area in which heat is generated when the command CMD and the data DATA are generated. The control device 150B may output the command CMD and the data DATA to the first memory device 160B and the second memory device 170B. The control device 150B may include the second area (120B, 120B-1, and 120B-2 illustrated in FIGS. 1, 2, 4, and 6) in which the command CMD and the data DATA are received from the first area and output to the first memory device 160B and the second memory device 170B. The memory device is not stacked on the first area. The first memory device 160B and the second memory device 170B may be disposed on the second area of the control device 150B.

The first memory device 160B and the second memory device 170B may each store data DATA by performing an internal operation and output the data DATA in each memory device based on the command CMD. The first memory device 160B and the second memory device 170B may each include the plurality of channels (CH1 to CH8 in FIGS. 3, 5, and 7) that independently operates. The plurality of channels (CH1 to CH8 in FIGS. 3, 5, and 7) may each store or output the data DATA by independently operating.

In an embodiment, the HBM device 17B can increase the bandwidth because the first memory device 160B and the second memory device 170B are connected to the control device 150B in common and input and output the data DATA. In an embodiment, the HBM device 17B can prevent or reduce heat from an area in which the command CMD and the data DATA are generated from being diffused to a memory device because the memory device is not stacked above the area in which the command CMD and the data DATA are generated. Interfaces that are connected to the TSVs of the control device 150B, the first memory device 160B, and the second memory device 170B may be various disposed of in the HBM device 17B.

The processor 19B may transmit the command CMD and the data DATA to the control device 150B through a wire formed within the interposer 15B, and may receive the data DATA from the control device 150B. The processor 19B may transmit various commands and signals that control internal operations of the control device 150B, the first memory device 160B, and the second memory device 170B, and may receive the results of the internal operations.

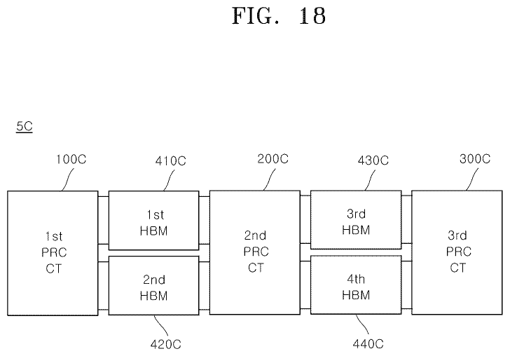

FIG. 18 is a block diagram illustrating a construction of semiconductor systems 5C according to an embodiment of the present disclosure. As illustrated in FIG. 18, the semiconductor system 5C may include a first process circuit (1st PRC CT) 100C, a second process circuit (2nd PRC CT) 200C, a third process circuit (3rd PRC CT) 300C, a first HBM device (1st HBM) 410C, a second HBM device (2nd HBM) 420C, a third HBM device (3rd HBM) 430C, and a fourth HBM device (4th HBM) 440C.

The first process circuit 100C may be electrically connected to the first HBM device 410C and the second HBM device 420C. The first process circuit 100C may be electrically connected to the first HBM device 410C and the second HBM device 420C through the interposer 15 illustrated in FIG. 17. The first process circuit 100C may control operations of the first HBM device 410C and the second HBM device 420C. The first process circuit 100C may perform an arithmetic operation by receiving data DATA from the first HBM device 410C and the second HBM device 420C.

The second process circuit 200C may be electrically connected to the first HBM device 410C and the second HBM device 420C. The second process circuit 200C may be electrically connected to the first HBM device 410C and the second HBM device 420C through the interposer 15 illustrated in FIG. 8. The second process circuit 200C may control operations of the first HBM device 410C and the second HBM device 420C. The second process circuit 200C may perform an arithmetic operation by receiving the data DATA from the first HBM device 410C and the second HBM device 420C. The second process circuit 200C may be electrically connected to the third HBM device 430C and the fourth HBM device 440C. The second process circuit 200C may be electrically connected to the third HBM device 430C and the fourth HBM device 440C through the interposer 15 illustrated in FIG. 17. The second process circuit 200C may control operations of the third HBM device 430C and the fourth HBM device 440C. The second process circuit 200C may perform an arithmetic operation by receiving data DATA from the third HBM device 430C and the fourth HBM device 440C. The second process circuit 200C may perform an arithmetic operation by receiving the data DATA from at least one of the first HBM device 410C, the second HBM device 420C, the third HBM device 430C, and the fourth HBM device 440C.

The third process circuit 300C may be electrically connected to the third HBM device 430C and the fourth HBM device 440C. The third process circuit 300C may be electrically connected to the third HBM device 430C and the fourth HBM device 440C through the interposer 15 illustrated in FIG. 17. The third process circuit 300C may control operations of the third HBM device 430C and the fourth HBM device 440C. The third process circuit 300C may perform an arithmetic operation by receiving the data DATA from the third HBM device 430C and the fourth HBM device 440C.

The first process circuit 100C, the second process circuit 200C, and the third process circuit 300C may each be implemented with a graphics processing unit (GPU) device and a neural processing unit (NPU) device.

The arithmetic operation may include a training operation and an inference operation. The training operation may be set as an operation of an artificial intelligence (AI) model learning a rule, a pattern, or a relation by optimizing weights and parameters from given data DATA. The inference operation may be set as an operation of an artificial intelligence (AI) model rapidly deriving results from new data by using weights learnt during the training operation.

The first HBM device 410C, the second HBM device 420C, the third HBM device 430C, and the fourth HBM device 440C may each include the control device 100B, the first memory device 200B, and the second memory device 300B illustrated in FIGS. 10 to 17. The first HBM device 410C, the second HBM device 420C, the third HBM device 430C, and the fourth HBM device 440C may each store data DATA and output the data DATA stored in each HBM device.

The physical area D2D PHY (111B, 111B-1, or 111B-2) illustrated in FIGS. 10, 11, 13, and 15 may be disposed at the boundary of each of the first HBM device 410C, the second HBM device 420C, the third HBM device 430C, and the fourth HBM device 440C. The first HBM device 410C, the second HBM device 420C, the third HBM device 430C, and the fourth HBM device 440C may be electrically connected to the first process circuit 100C, the second process circuit 200C, and the third process circuit 300C through the physical area D2D PHY. The first HBM device 410C, the second HBM device 420C, the third HBM device 430C, and the fourth HBM device 440C may be shared by the first process circuit 100C, the second process circuit 200C, and the third process circuit 300C through the physical area D2D PHY.

The semiconductor system 5C according to an embodiment of the present disclosure has a plurality of HBM devices electrically connected to a plurality of process circuits, and can extend the capacity of data that is used in an arithmetic operation of the process circuit. The semiconductor system 5C has a plurality of HBM devices shared by a plurality of process circuits, and can extend the number of process circuits used in an arithmetic operation. The semiconductor system 5C can rapidly perform an arithmetic operation because a plurality of HBM devices is electrically connected to a plurality of process circuits to perform the arithmetic operation.

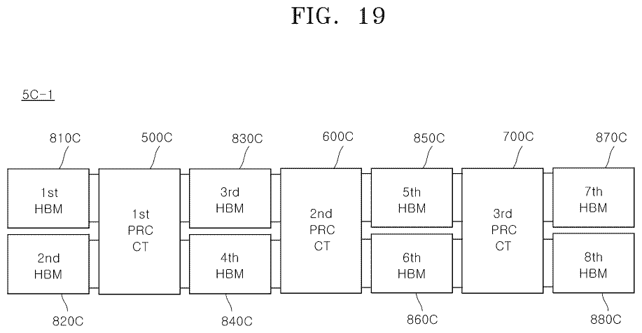

FIG. 19 is a block diagram illustrating a construction of a semiconductor system 5C-1 according to an embodiment of the present disclosure. As illustrated in FIG. 19, the semiconductor system 5C-1 may include a first process circuit (1st PRC CT) 500C, a second process circuit (2nd PRC CT) 600C, a third process circuit (3rd PRC CT) 700C, a first HBM device (1st HBM) 810C, a second HBM device (2nd HBM) 820C, a third HBM device (3rd HBM) 830C, a fourth HBM device (4th HBM) 840C, a fifth HBM device (5th HBM) 850C, a sixth HBM device (6th HBM) 860C, a seventh HBM device (7th HBM) 870C, and an eighth HBM device (8th HBM) 880C.

The first process circuit 500C may be electrically connected to the first HBM device 810C and the second HBM device 820C. The first process circuit 500C may be electrically connected to the first HBM device 810C and the second HBM device 820C through the interposer 15 illustrated in FIG. 17. The first process circuit 500C may control operations of the first HBM device 810C and the second HBM device 820C. The first process circuit 500C may perform an arithmetic operation by receiving data DATA from the first HBM device 810C and the second HBM device 820C. The first process circuit 500C may be electrically connected to the third HBM device 830C and the fourth HBM device 840C. The first process circuit 500C may be electrically connected to the third HBM device 830C and the fourth HBM device 840C through the interposer 15 illustrated in FIG. 17. The first process circuit 500C may control operations of the third HBM device 830C and the fourth HBM device 840C. The first process circuit 500C may perform an arithmetic operation by receiving data DATA from the third HBM device 830C and the fourth HBM device 840C. The first process circuit 500C may perform an arithmetic operation by receiving the data DATA from at least any one of the first HBM device 810C, the second HBM device 820C, the third HBM device 830C, and the fourth HBM device 840C.

The second process circuit 600C may be electrically connected to the third HBM device 830C and the fourth HBM device 840C. The second process circuit 600C may be electrically connected to the third HBM device 830C and the fourth HBM device 840C through the interposer 15 illustrated in FIG. 17. The second process circuit 600C may control operations of the third HBM device 830C and the fourth HBM device 840C. The second process circuit 600C may perform an arithmetic operation by receiving the data DATA from the third HBM device 830C and the fourth HBM device 840C. The second process circuit 600C may be electrically connected to the fifth HBM device 850C and the sixth HBM device 860C. The second process circuit 600C may be electrically connected to the fifth HBM device 850C and the sixth HBM device 860C through the interposer 15 illustrated in FIG. 17. The second process circuit 600C may control operations of the fifth HBM device 850C and the sixth HBM device 860C. The second process circuit 600C may perform an arithmetic operation by receiving data DATA from the fifth HBM device 850C and the sixth HBM device 860C. The second process circuit 600C may perform an arithmetic operation by receiving the data DATA from at least any one of the third HBM device 830C, the fourth HBM device 840C, the fifth HBM device 850C, and the sixth HBM device 860C.

The third process circuit 700C may be electrically connected to the fifth HBM device 850C and the sixth HBM device 860C. The third process circuit 700C may be electrically connected to the fifth HBM device 850C and the sixth HBM device 860C through the interposer 15 illustrated in FIG. 17. The third process circuit 700C may control operations of the fifth HBM device 850C and the sixth HBM device 860C. The third process circuit 700C may perform an arithmetic operation by receiving the data DATA from the fifth HBM device 850C and the sixth HBM device 860C. The third process circuit 700C may be electrically connected to the seventh HBM device 870C and the eighth HBM device 880C. The third process circuit 700C may be electrically connected to the seventh HBM device 870C and the eighth HBM device 880C through the interposer 15 illustrated in FIG. 17. The third process circuit 700C may control operations of the seventh HBM device 870C and the eighth HBM device 880C. The third process circuit 700C may perform an arithmetic operation by receiving data DATA from the seventh HBM device 870C and the eighth HBM device 880C. The third process circuit 700C may perform an arithmetic operation by receiving the data DATA from at least any one of the fifth HBM device 850C, the sixth HBM device 860C, the seventh HBM device 870C, and the eighth HBM device 880C.

The first process circuit 500C, the second process circuit 600C, and the third process circuit 700C may each be implemented with a graphics processing unit (GPU) device and a neural processing unit (NPU) device.

The first HBM device 810C, the second HBM device 820C, the third HBM device 830C, the fourth HBM device 840C, the fifth HBM device 850C, the sixth HBM device 860C, the seventh HBM device 870C, and the eighth HBM device 880C may each include the control device 100B, the first memory device 200B, and the second memory device 300B illustrated in FIGS. 10 to 17. The first HBM device 810C, the second HBM device 820C, the third HBM device 830C, the fourth HBM device 840C, the fifth HBM device 850C, the sixth HBM device 860C, the seventh HBM device 870C,I and the eighth HBM device 880C may each store data DATA and output the data DATA stored in each HBM device.

The physical area D2D PHY (111B, 111B-1, or 111B-2) illustrated in FIGS. 10, 11, 13, and 15 may be disposed at the boundary of each of the first HBM device 810C, the second HBM device 820C, the third HBM device 830C, the fourth HBM device 840C, the fifth HBM device 850C, the sixth HBM device 860C, the seventh HBM device 870C, and the eighth HBM device 880C. The first HBM device 810C, the second HBM device 820C, the third HBM device 830C, the fourth HBM device 840C, the fifth HBM device 850C, the sixth HBM device 860C, the seventh HBM device 870C, and the eighth HBM device 880C may be electrically connected to the first process circuit 500C, the second process circuit 600C, and the third process circuit 700C through the physical area D2D PHY. The first HBM device 810C, the second HBM device 820C, the third HBM device 830C, the fourth HBM device 840C, the fifth HBM device 850C, the sixth HBM device 860C, the seventh HBM device 870C, and the eighth HBM device 880C may be shared by the first process circuit 500C, the second process circuit 600C, and the third process circuit 700C through the physical area D2D PHY.

The semiconductor system 5C-1 according to an embodiment of the present disclosure has a plurality of HBM devices electrically connected to a plurality of process circuits, and can extend the capacity of data that is used in an arithmetic operation of the process circuit. The semiconductor system 5C-1 has a plurality of HBM devices shared by a plurality of process circuits, and can extend the number of process circuits used in an arithmetic operation. The semiconductor system 5C-1 can rapidly perform an arithmetic operation because a plurality of HBM devices is electrically connected to a plurality of process circuits to perform the arithmetic operation.

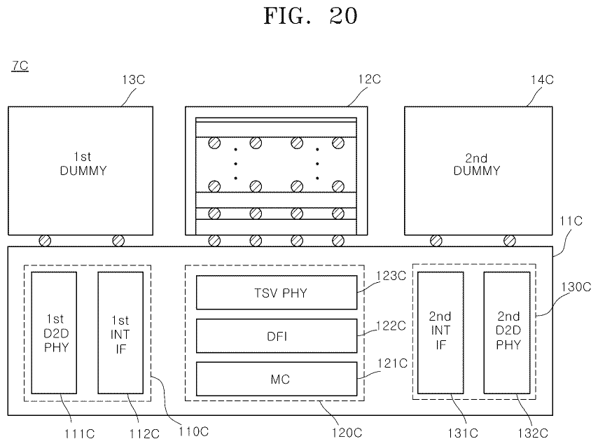

FIG. 20 is a block diagram illustrating a construction of an HBM device 7C according to an embodiment of the present disclosure. As illustrated in FIG. 20, the HBM device 7C may include a control device 11C, a memory device 12C, a first dummy die group (1st DUMMY) 13C, and a second dummy die group (2nd DUMMY) 14C.

The control device 11C may be implemented with the base die 111 of FIGS. 1 and 2. The control device 11C may be implemented with the base die 131 of FIG. 3. The control device 11C may be implemented with the base die 171 of FIG. 4.

The control device 11C may generate a command CMD and data DATA. The control device 11C may output the command CMD and the data DATA to the memory device 12C. The control device 11C may receive data DATA from the memory device 12C. The control device 11C may be implemented with a base chip, a controller, etc. that controls an operation of the memory device 12C.

The control device 11C may include a first area 110C, a second area 120C, and a third area 130C. An upper part of the first area 110C may be set as a first setting space. An upper part of the second area 120C may be set as a second setting space. An upper part of the third area 130C may be set as a third setting space. The first area 110C may be set as an area that generates a command CMD and data DATA and inputs and outputs the command CMD and the data DATA. Heat may be generated when the first area 110 inputs and outputs the command CMD and the data DATA. The second area 120C may be set as an area that receives the command CMD and the data DATA from the first area 110C and outputs the command CMD and the data DATA to the memory device 12C and that receives the data DATA from the memory device 12C and outputs the data DATA to the first area 110C and the third area 130C. The third area 130C may be set as an area that receives the command CMD and the data DATA and inputs and outputs the command CMD and the data DATA. The third area 130C may be set as an area that inputs and outputs the command CMD and the data DATA to and from another HBM device, a process circuit, or an external device. Heat may be generated when the third area 130C inputs and outputs the command CMD and the data DATA.

The first area 110C may include a first physical area (1st D2D PHY) 111C and a first internal interface area (1st INT IF) 112C.

The first physical area 111C may generate a command CMD and data DATA based on a signal that is received from the process circuit (PRC CT in FIGS. 18 and 19). The first physical area 111C may output the command CMD and the data DATA to the first internal interface area 112C. The first physical area 111C may receive the data DATA from the first internal interface area 112C and output the data DATA to the process circuit (PRC CT in FIGS. 18 and 19). The first physical area 111C may be implemented with a physical layer PHY that is responsible for the generation, transmission, reception, and physical connection of signals and data between an external device and the control device 11C.

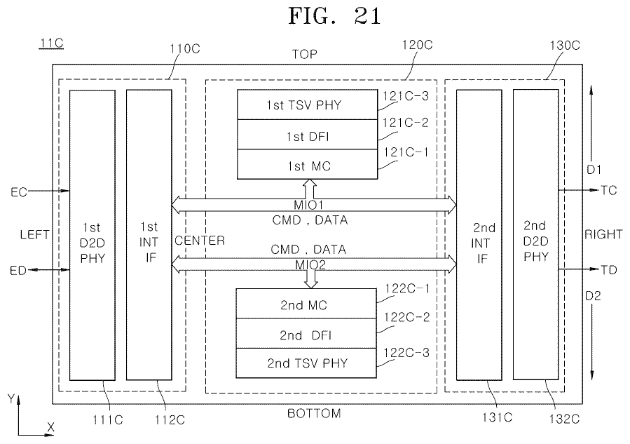

The first internal interface area 112C may receive the command CMD and the data DATA from the first physical area 111C. The first internal interface area 112C may output the command CMD and the data DATA to internal input and output lines (MIO1 and MIO2 in FIG. 21) by adjusting the input and output sequence of the command CMD and the data DATA. The first internal interface area 112C may receive the data DATA from the internal input and output lines (MIO1 and MIO2 in FIG. 21) and output the data DATA to the first physical area 111C. The first internal interface area 112C may output the command CMD and the data DATA to the second area 120C and the third area 130C by adjusting the input and output sequence of the command CMD and the data DATA. The first internal interface area 112C may be implemented with an interface that defines the timing and sequence of signals that are transmitted between the physical layer PHY and internal circuits and that inputs and outputs the signals. The first internal interface area 112C and the internal input and output lines (MIO1 and MIO2 in FIG. 21) may be implemented in a network-on-chip (NoC). The network-on-chip (NoC) may be set as a transmission path that connects several types of internal circuits within a chip.

The second area 120C may include a memory controller (MC) 121C, a base interface area (DFI) 122C, and a base TSV area (TSV PHY) 123C.

The memory controller 121C may receive a command CMD and data DATA through the internal input and output lines (MIO1 and MIO2 in FIG. 21). The memory controller 121C may output the command CMD and the data DATA that control an operation of the memory device 12C to the base interface area 122C. The memory controller 121C may receive the data DATA from the base interface area 122C and output the data DATA to the internal input and output lines (MIO1 and MIO2 in FIG. 21).

The base interface area 122C may receive the command CMD and the data DATA from the memory controller 121C. The base interface area 122C may output the command CMD and the data DATA to the base TSV area 123C by adjusting the input and output sequence of the command CMD and the data DATA. The base interface area 122C may receive data DATA from the base TSV area 123C and output the data DATA to the memory controller 121C.

The base TSV area 123C may receive the command CMD and the data DATA from the base interface area 122C. The base TSV area 123C may output the command CMD and the data DATA to the memory device 12C through a plurality of TSVs. The base TSV area 123C may receive the data DATA from the memory device 12C and output the data DATA to the base interface area 122C.

The memory controller 121C, the base interface area 122C, and the base TSV area 123C may be disposed in the horizontal direction of the control device 11C of the control device 11C.

The third area 130C may include a second internal interface area (2nd INT IF) 131C and a second physical area (2nd D2D PHY) 132C.

The second internal interface area 131C may receive the command CMD and the data DATA from the internal input and output lines (MIO1 and MIO2 in FIG. 21). The second internal interface area 131C may output the command CMD and the data DATA to the second physical area 132C by adjusting the input and output sequence of the command CMD and the data DATA. The second internal interface area 131C may be implemented with an interface that defines the timing and sequence of signals that are transmitted between the physical layer PHY and internal circuits and that inputs and outputs the signals. The second internal interface area 131C may be implemented in a network-on-chip (NoC).

The second physical area 132C may receive the command CMD and the data DATA from the second internal interface area 131C. The second physical area 132C may output to the command CMD and the data DATA to another HBM device and the process circuit (PRC CT in FIGS. 18 and 19). The second physical area 132C may be implemented with a physical layer PHY that is responsible for the generation, transmission, reception, and physical connection of signals and data between the external device and the control device 11C.

The memory device 12C may include a plurality of core dies that is vertically stacked. The memory device 12C may be disposed in the second setting space. The memory device 12C may receive the command CMD and the data DATA from the base TSV area 123C. The memory device 12C may perform an internal operation based on the command CMD and the data DATA. The memory device 12C may store the data DATA in the plurality of core dies based on the command CMD after the start of a write operation. The memory device 12C may output the data DATA stored in the plurality of core dies to the base TSV area 123C based on the command CMD after the start of a read operation.

The first dummy die group 13C may be vertically stacked on the first area 110C of the control device 11C. The first dummy die group 13C may be disposed in the first setting space. The first dummy die group 13C may be implemented with a plurality of dummy dies (not illustrated) that is stacked. The first dummy die group 13C may have the same height as the memory device 12C. The plurality of dummy dies (not illustrated) included in the first dummy die group 13C may have the same height as the plurality of core dies (not illustrated) included in the memory device 12C. The first dummy die group 13C may be one dummy die according to an embodiment. The first setting space in which the first dummy die group 13C is formed may be an empty space according to an embodiment. The first dummy die group 13C may discharge heat that is generated from the first area 110C of the control device 11C. The plurality of dummy dies (not illustrated) included in the first dummy die group 13C may be connected through a plurality of TSVs through a plurality of micro bump pads, thus facilitating the discharge of heat.

The second dummy die group 14C may be vertically stacked on the third area 130C of the control device 11C. The second dummy die group 14C may be disposed in the third setting space. The second dummy die group 14C may be implemented with a plurality of dummy dies (not illustrated) that is stacked. The second dummy die group 14C may have the same height as the memory device 12C. The plurality of dummy dies (not illustrated) included in the second dummy die group 14C may have the same height as the plurality of core dies (not illustrated) included in the memory device 12C. The second dummy die group 14C may be one dummy die according to an embodiment. The third setting space in which the second dummy die group 14C is formed may be an empty space according to an embodiment. The second dummy die group 14C may discharge heat that is generated from the third area 130C of the control device 11C. The plurality of dummy dies (not illustrated) included in the second dummy die group 14C may be connected through a plurality of TSVs through a plurality of micro bump pads, thus facilitating the discharge of heat.

The HBM device 7C according to an embodiment of the present disclosure can prevent a phenomenon in which generated heat is diffused to a memory device because the memory device is not stacked on an area from which the heat is generated due to the input and output of the command CMD and the data DATA. The HBM device 7C according to an embodiment of the present disclosure can facilitate the discharge of heat because a dummy die group is stacked on an area from which the heat is generated due to the input and output of the command CMD and the data DATA.

FIG. 21 is a block diagram illustrating a construction of the control device 11C according to an embodiment of the present disclosure. As illustrated in FIG. 21, the control device 11C may include the first area 110C, the second area 120C, and the third area 130C.

The first area 110C may include the first physical area 111C and the first internal interface area 112C.

The first physical area 111C may generate the command CMD by receiving an external command EC from the process circuit (PRC CT in FIGS. 18 and 19). The first physical area 111C may generate the command CMD by buffering or decoding the external command EC. The external command EC and the command CMD are each illustrated as only one signal, but may each include a plurality of bits. The first physical area 111C may generate the data DATA by receiving external data ED from the process circuit (PRC CT in FIGS. 18 and 19). The first physical area 111C may generate the external data ED by receiving data DATA from the first internal interface area 112C. The first physical area 111C may output the external data ED to the process circuit (PRC CT in FIGS. 18 and 19). The external data ED and the data DATA are each illustrated as only one signal, but may each include a plurality of bits.

The first internal interface area 112C may receive the command CMD and the data DATA from the first physical area 111C. The first internal interface area 112C may output the command CMD and the data DATA that control an operation of the memory device 12C to the first internal input and output line MIO1 by adjusting the input and output sequence of the command CMD and the data DATA. The first internal interface area 112C may output the command CMD and the data DATA that control an operation of the memory device 12C to the second internal input and output line MIO2 by adjusting the input and output sequence of the command CMD and the data DATA. The first internal input and output line MIO1 and the second internal input and output line MIO2 may be disposed in a central area CENTER of the control device 11C. The first internal interface area 112C, the first internal input and output line MIO1, and the second internal input and output line MIO2 may be implemented in a network-on-chip (NoC).

The first area 110C may be set as an area that generates a command CMD and data DATA and inputs and outputs the command CMD and the data DATA. Heat may be generated when the first area 110C inputs and outputs the command CMD and the data DATA. The first area 110C may be disposed in a left area LEFT of the control device 11C in an X axis.

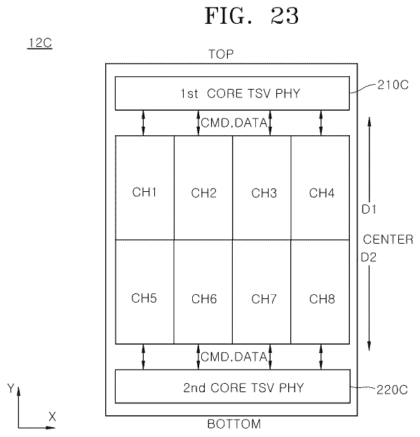

The second area 120C may include a first memory controller (1st MC) 121C-1, a first base interface area (1st DFI) 121C-2, a first base TSV area (1st TSV PHY) 121C-3, a second memory controller (2nd MC) 122C-1, a second base interface area (2nd DFI) 122C-2, and a second base TSV area (2nd TSV PHY) 122C-3 that control an operation of the memory device 12C. The first memory controller 121C-1, the first base interface area 121C-2, and the first base TSV area 121C-3 may be components that control an operation of a first group of channels (CH1 to CH4 in FIG. 23) included in the memory device 12C. The second memory controller 122C-1, the second base interface area 122C-2, and the second base TSV area 122C-3 may be components that control an operation of a second group of channels (CH5 to CH8 in FIG. 23) included in the memory device 12C. Each of the first memory controller 121C-1, the first base interface area 121C-2, and the first base TSV area 121C-3, and the second memory controller 122C-1, the second base interface area 122C-2, and the second base TSV area 122C-3 may be implemented with the memory controller 121C, the base interface area 122C, and the base TSV area 123C illustrated in FIG. 20.

The first memory controller 121C-1, the first base interface area 121C-2, and the first base TSV area 121C-3, and the second memory controller 122C-1, the second base interface area 122C-2, and the second base TSV area 122C-3 may be disposed in the horizontal direction of the control device 11C.

The first memory controller 121C-1 may be electrically connected to the first internal input and output line MIO1. The first memory controller 121C-1 may receive the command CMD and the data DATA that control an operation of the first group of channels (CH1 to CH4 in FIG. 23) included in the memory device 12C through the first internal input and output line MIO1. The first memory controller 121C-1 may output the command CMD and the data DATA that control an operation of the first group of channels (CH1 to CH4 in FIG. 23) included in the memory device 12C. The first memory controller 121C-1 may receive the data DATA from the first base interface area 121C-2 and output the data DATA to the first internal input and output line MIO1.

The first base interface area 121C-2 may be electrically connected to the first memory controller 121C-1. The first base interface area 121C-2 may receive the command CMD and the data DATA from the first memory controller 121C-1. The first base interface area 121C-2 may output the command CMD and the data DATA to the first base TSV area 121C-3 by adjusting the input and output sequence of the command CMD and the data DATA. The first base interface area 121C-2 may receive the data DATA from the first base TSV area 121C-3 and output the data DATA to the first memory controller 121C-1.

The first base TSV area 121C-3 may be electrically connected to the first base interface area 121C-2. The first base TSV area 121C-3 may receive the command CMD and the data DATA from the first base interface area 121C-2. The first base TSV area 121C-3 may output the command CMD and the data DATA to a first core TSV area (1st CORE TSV PHY) (210C in FIG. 23) included in the memory device 12C through a plurality of TSVs. The first base TSV area 121C-3 may receive the data DATA from the memory device 12C and output the data DATA to the first base interface area 121C-2.

The first memory controller 121C-1, the first base interface area 121C-2, and the first base TSV area 121C-3 may be sequentially disposed in a first direction D1 from the central area CENTER of the control device 11C. The first direction D1 may be set as a direction from the central area CENTER to a first edge area TOP. The first edge area TOP may be set as an upper area of the control device 11C in a Y axis.

The second memory controller 122C-1 may be electrically connected to the second internal input and output line MIO2. The second memory controller 122C-1 may receive the command CMD and the data DATA that control an operation of the second group of channels (CH5 to CH8 in FIG. 23) included in the memory device 12C through the second internal input and output line MIO2. The second memory controller 122C-1 may output the command CMD and the data DATA that control an operation of the second group of channels (CH5 to CH8 in FIG. 23) included in the memory device 12C. The second memory controller 122C-1 may receive the data DATA from the second base interface area 122C-2 and output the data DATA to the second internal input and output line MIO2.

The second base interface area 122C-2 may be electrically connected to the second memory controller 122C-1. The second base interface area 122C-2 may receive the command CMD and the data DATA from the second memory controller 122C-1. The second base interface area 122C-2 may output the command CMD and the data DATA to the second base TSV area 122C-3 by adjusting the input and output sequence of the command CMD and the data DATA. The second base interface area 122C-2 may receive the data DATA from the second base TSV area 122C-3 and output the data DATA to the second memory controller 121C-2.

The second base TSV area 122C-3 may be electrically connected to the second base interface area 122C-2. The second base TSV area 122C-3 may receive the command CMD and the data DATA from the second base interface area 122C-2. The second base TSV area 122C-3 may output the command CMD and the data DATA to a second core TSV area (220C in FIG. 23) included in the memory device 12C through a plurality of TSVs. The second base TSV area 122C-3 may receive the data DATA from the memory device 12C and output the data DATA to the second base interface area 122C-2.

The second memory controller 122C-1, the second base interface area 122C-2, and the second base TSV area 122C-3 may be sequentially disposed in a second direction D2 from the central area CENTER of the control device 11C. The second direction D2 may be set as a direction from the central area CENTER to a second edge area BOTTOM. The second edge area BOTTOM may be set as a lower area of the control device 11C in the Y axis.

The second area 120C may be set as an area that receives the command CMD and the data DATA from the first area 110C and outputs the command CMD and the data DATA to the memory device 12C. The second area 120C may be disposed in the central area CENTER of the control device 11C in the X axis.

The third area 130C may include the second internal interface area 131C and the second physical area 132C.

The second internal interface area 131C may receive the command CMD and the data DATA from the first internal input and output line MIO1. The second internal interface area 131C may output the command CMD and the data DATA received through the first internal input and output line MIO1 to the second physical area 132C by adjusting the input and output sequence of the command CMD and the data DATA. The second internal interface area 131C may receive the command CMD and the data DATA from the second internal input and output line MIO2. The second internal interface area 131C may output the command CMD and the data DATA received through the second internal input and output line MIO2 to the second physical area 132C by adjusting the input and output sequence of the command CMD and the data DATA. The second internal interface area 131C may be implemented in a network-on-chip (NoC).

The second physical area 132C may receive the command CMD and the data DATA from the second internal interface area 131C. The second physical area 132C may output the command CMD that is received as a transfer command TC. The second physical area 132C may output the data DATA that are received as transfer data TD. The second physical area 132C may output the transfer command TC and the transfer data TD to another HBM device and the process circuit (PRC CT in FIGS. 18 and 19).

The third area 130C may be set as an area that receives the command CMD and the data DATA from the second area 120C. The third area 130C may be set as an area that inputs and outputs the transfer command TC and the transfer data TD that are generated from the command CMD and the data DATA that are received. The third area 130C may be set as an area that inputs and outputs the command CMD and the data DATA to and from another HBM device, a process circuit, or an external device. The third area 130C may be disposed in a right area RIGHT of the control device 11C in the X axis.

In FIG. 21, the first internal interface area 112C, the second internal interface area 131C, the first internal input and output line MIO1, and the second internal input and output line MIO2 that are implemented in the network-on-chip (NoC) may be implemented in a first form. The first form means a form in which the first internal input and output line MIO1 and the second internal input and output line MIO2 that are implemented in the transverse direction of the control device 11C in the X axis direction are disposed between the first internal interface area 112C and the second internal interface area 131C that are implemented in the longitudinal direction of the control device 11C in the Y axis direction.

In the first form, the first memory controller 121C-1, the first base interface area 121C-2, and the first base TSV area 121C-3 may be sequentially disposed in the first direction D1 from the central area CENTER in which the first internal input and output line MIO1 is disposed. In the first form, the second memory controller 122C-1, the second base interface area 122C-2, and the second base TSV area 122C-3 may be sequentially disposed in the second direction D2 from the central area CENTER in which the second internal input and output line MIO2 is disposed.

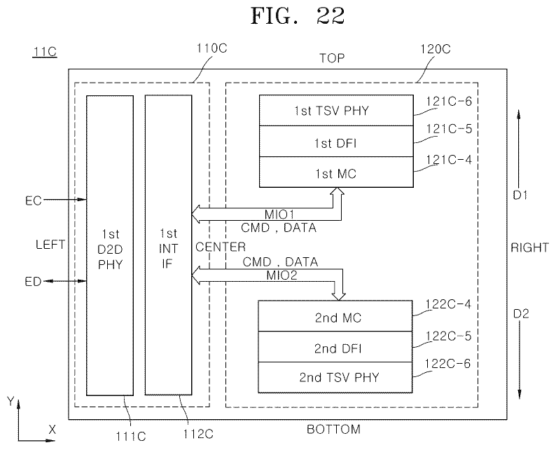

FIG. 22 is a block diagram illustrating a construction of the control device 11C according to an embodiment of the present disclosure. As illustrated in FIG. 22, the control device 11C may include the first area 110C and the second area 120C.

The first area 110C may include the first physical area 111C and the first internal interface area 112C.

The first physical area 111C and the first internal interface area 112C have the same constructions as the first physical area 111C and the first internal interface area 112C illustrated in FIG. 21, and thus detailed descriptions thereof are omitted.

The first internal input and output line MIO1 illustrated in FIG. 22 is connected between the first internal interface area 112C and the first memory controller 121C-4 differently from the first internal input and output line MIO1 illustrated in FIG. 21, and may input and output a command CMD and data DATA. The second internal input and output line MIO2 illustrated in FIG. 22 is connected between the first internal interface area 112C and the second memory controller 122C-4 differently from the second internal input and output line MIO2 illustrated in FIG. 21, and may input and output a command CMD and data DATA. The first internal input and output line MIO1 and the second internal input and output line MIO2 may each be implemented with a network-on-chip (NoC).

The first area 110C may be set as an area that generates a command CMD and data DATA and inputs and outputs the command CMD and the data DATA. Heat may be generated when the first area 110C inputs and outputs the command CMD and the data DATA. The first area 110C may be disposed in a left area LEFT of the control device 11C in an X axis.

The second area 120C may include a first memory controller (1st MC) 121C-4, a first base interface area (1st DFI) 121C-5, a first base TSV area (1st TSV PHY) 121C-6, a second memory controller (2nd MC) 122C-4, a second base interface area (2nd DFI) 122C-5, and a second base TSV area (2nd TSV PHY) 122C-6 that control an operation of the memory device 12C.

The first memory controller 121C-4, the first base interface area 121C-5, the first base TSV area 121C-6, the second memory controller 122C-4, the second base interface area 122C-5, and the second base TSV area 122C-6 have the same constructions as the first memory controller 121C-1, the first base interface area 121C-2, the first base TSV area 121C-3, the second memory controller 122C-1, the second base interface area 122C-2, and the second base TSV area 122C-3 illustrated in FIG. 21, and thus detailed descriptions thereof are omitted.

The second area 120C may be set as an area that receives the command CMD and the data DATA from the first area 110C and outputs the command CMD and the data DATA to the memory device 12C. The second area 120C may be disposed in a right area RIGHT of the control device 11C in the X axis.

In FIG. 22, the first internal interface area 112C, the first internal input and output lines MIO1, and the second internal input and output line MIO2 that are implemented in the network-on-chip (NoC) may be implemented in a second form. The second form means a form in which the first internal interface area 112C that is implemented in the longitudinal direction of the control device 11C in a Y axis direction and the first internal input and output line MIO1 and the second internal input and output line MIO2 that are implemented in the transverse direction of the control device 11C in the X axis direction are disposed.

In the second form, the first memory controller 121C-4, the first base interface area 121C-5 and the first base TSV area 121C-6 may be sequentially disposed in the first direction D1 from a central area CENTER in which the first internal input and output line MIO1 are disposed. In the second form, the second memory controller 122C-4, the second base interface area 122C-5, and the second base TSV area 122C-6 may be sequentially disposed in a second direction D2 from the central area CENTER in which the second internal input and output line MIO2 is disposed.

FIG. 23 is a block diagram illustrating a construction of the memory device 12C according to an embodiment of the present disclosure.

The memory device 12C may include the first to eighth channels CH1 to CH8, the first core TSV area 210C, and the second core TSV area 220C.

The first to eighth channels CH1 to CH8 may receive the command CMD and the data DATA by independently performing internal operations. The first to eighth channels CH1 to CH8 may each store data DATA based on a command CMD after the start of a write operation of an internal operation. The first to eighth channels CH1 to CH8 may each output the data DATA based on the command CMD after the start of a read operation of an internal operation.

The first to fourth channels CH1 to CH4 may be electrically connected to the first core TSV area 210C. The first to fourth channels CH1 to CH4 may receive the command CMD and the data DATA from the first core TSV area 210C. The first to fourth channels CH1 to CH4 may output the data DATA to the first core TSV area 210C. The first to fourth channels CH1 to CH4 may each store data DATA based on a command CMD after the start of a write operation of an internal operation. The first to fourth channels CH1 to CH4 may each output the data DATA based on the command CMD after the start of a read operation of an internal operation. The first to fourth channels CH1 to CH4 may be set as the first group of channels.

The fifth to eighth channels CH5 to CH8 may be electrically connected to the second core TSV area 220C. The fifth to eighth channels CH5 to CH8 may receive a command CMD and data DATA from the second core TSV area 220C. The fifth to eighth channels CH5 to CH8 may output the data DATA to the second core TSV area 220C. The fifth to eighth channels CH5 to CH8 may each store data DATA based on a command CMD after the start of a write operation of an internal operation. The fifth to eighth channels CH5 to CH8 may each output the data DATA based on the command CMD after the start of a read operation of an internal operation. The fifth to eighth channels CH5 to CH8 may be set as the second group of channels.

The first to fourth channels CH1 to CH4 may be disposed in a central area CENTER of the memory device 12C. The fifth to eighth channels CH5 to CH8 may be disposed in the central area CENTER of the memory device 12C.

The first core TSV area 210C may be electrically connected to the first base TSV area 121C-3, 121C-6 of the control device 11C. The first core TSV area 210C may receive the command CMD and the data DATA from the first base TSV area 121C-3, 121C-6. The first core TSV area 210C may receive the command CMD and the data DATA through a plurality of TSVs. The first core TSV area 210C may output the command CMD and the data DATA to the first to fourth channels CH1 to CH4. The first core TSV area 210 may receive the data DATA from the first to fourth channels CH1 to CH4 and output the data DATA to the first base TSV area 121C-3, 121C-6. The first core TSV area 210C may be disposed in a first direction D1 from the central area CENTER. The first direction D1 may be set as a direction from the central area CENTER to a first edge area TOP. The first edge area TOP may be set as an upper area of the memory device 12C in a Y axis.

The second core TSV area 220C may be electrically connected to the second base TSV area 122C-3, 122C-6 of the control device 11C. The second core TSV area 220C may receive the command CMD and the data DATA from the second base TSV area 122C-3, 122C-6. The second core TSV area 220C may receive the command CMD and the data DATA through a plurality of TSVs. The second core TSV area 220C may output the command CMD and the data DATA to the fifth to eighth channels CH5 to CH8. The second core TSV area 220C may receive the data DATA from the fifth to eighth channels CH5 to CH8 and output the data DATA to the second base TSV area 122C-3, 122C-6. The second core TSV area 220C may be disposed in a second direction D2 from the central area CENTER. The second direction D2 may be set as a direction from the central area CENTER to a second edge area BOTTOM. The second edge area BOTTOM may be set as a lower area of the memory device 12C in the Y axis.

The HBM device 7C according to an embodiment of the present disclosure can prevent a phenomenon in which generated heat is diffused to a memory device because the memory device is not stacked on an area from which the heat is generated due to the input and output of the command CMD and the data DATA. The HBM device 7C according to an embodiment of the present disclosure can facilitate the discharge of heat because a dummy die group is stacked on an area from which the heat is generated due to the input and output of the command CMD and the data DATA.

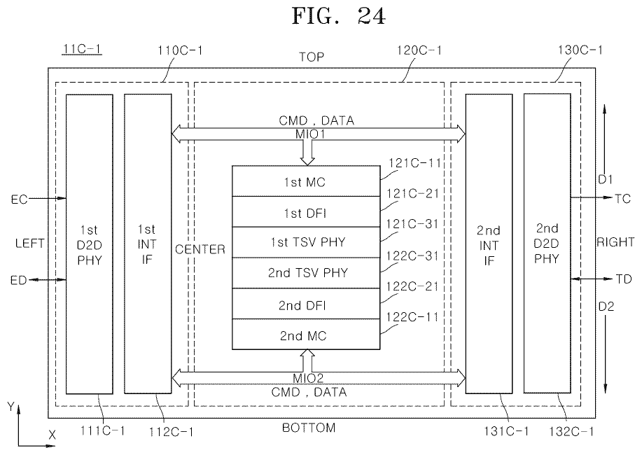

FIG. 24 is a block diagram illustrating a construction of a control device 11C-1 according to an embodiment of the present disclosure. As illustrated in FIG. 24, the control device 11C-1 may include a first area 110C-1, a second area 120C-1, and a third area 130C-1.

The first area 110C-1 may include a first physical area (1st D2D PHY) 111C-1 and a first internal interface area (1st INT IF) 112C-1.

The first physical area 111C-1 may generate a command CMD by receiving an external command EC from the process circuit (PRC CT in FIGS. 18 and 19). The first physical area 111C-1 may generate the command CMD by buffering or decoding the external command EC. The external command EC and the command CMD are each illustrated as only one signal, but may each include a plurality of bits. The first physical area 111C-1 may generate data DATA by receiving external data ED from the process circuit (PRC CT in FIGS. 18 and 19). The first physical area 111C-1 may generate the external data ED by receiving data DATA from the first internal interface area 112C-1. The first physical area 111C-1 may output the external data ED to the process circuit (PRC CT in FIGS. 18 and 19). The external data ED and the data DATA are each illustrated as only one signal, but may each include a plurality of bits.

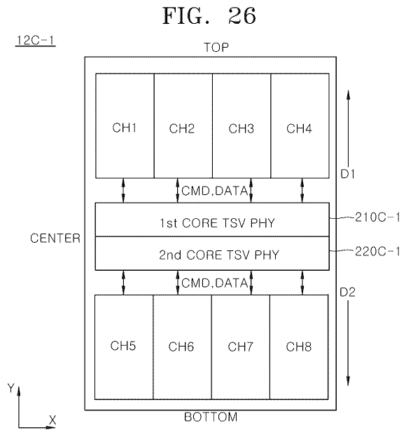

The first internal interface area 112C-1 may receive the command CMD and the data DATA from the first physical area 111C-1. The first internal interface area 112C-1 may output command CMD and the data DATA that control an operation of the memory device (12C-1 in FIG. 26) to a first internal input and output line MIO1 by adjusting the input and output sequence of the command CMD and the data DATA. The first internal interface area 112C-1 may output the command CMD and the data DATA that control an operation of the memory device (12C-1 in FIG. 26) to a second internal input and output line MIO2 by adjusting the input and output sequence of the command CMD and the data DATA. The first internal input and output line MIO1 may be disposed in a first edge area TOP of the control device 11C-1. The second internal input and output line MIO2 may be disposed in a second edge area BOTTOM of the control device 11C-1. The first internal interface area 112C-1, the first internal input and output line MIO1, and the second internal input and output line MIO2 may be implemented in a network-on-chip (NoC).

The first area 110C-1 may be set as an area that generates a command CMD and data DATA and inputs and outputs the command CMD and the data DATA. Heat may be generated when the first area 110C-1 inputs and outputs the command CMD and the data DATA. The first area 110C-1 may be disposed in a left area LEFT of the control device 11C-1 in a X axis.

The second area 120C-1 may include a first memory controller (1st MC) 121C-11, a first base interface area (1st DFI) 121C-21, a first base TSV area (1st TSV PHY) 121C-31, a second memory controller (2nd MC) 122C-11, a second base interface area (2nd DFI) 122C-21, and a second base TSV area (2nd TSV PHY) 122C-31 that control an operation of the memory device 12C. The first memory controller 121C-11, the first base interface area 121C-21, and the first base TSV area 121C-31 may be components that control an operation of a first group of channels (CH1 to CH4 in FIG. 24) included in a memory device (12C-1 in FIG. 26). The second memory controller 122C-11, the second base interface area 122C-21, and the second base TSV area 122C-31 may be components that control an operation of a second group of channels (CH5 to CH8 in FIG. 26) included in the memory device (12C-1 in FIG. 26). Each of the first memory controller 121C-11, the first base interface area 121C-21, and the first base TSV area 121C-31, and the second memory controller 122C-11, the second base interface area 122C-21, and the second base TSV area 122C-31 may be implemented with the memory controller 121C, the base interface area 122C, and the base TSV area 123C illustrated in FIG. 20.

The first memory controller 121C-11, the first base interface area 121C-21, the first base TSV area 121C-31, the second memory controller 122C-11, the second base interface area 122C-21, and the second base TSV area 122C-31 may be disposed in the horizontal direction of the control device 11C-1.

The first memory controller 121C-11 may be electrically connected to the first internal input and output line MIO1. The first memory controller 121C-11 may receive the command CMD and the data DATA that control an operation of the first group of channels (CH1 to CH4 in FIG. 26) included in the memory device (12C-1 in FIG. 26) through the first internal input and output line MIO1. The first memory controller 121C-11 may output the command CMD and the data DATA that control an operation of the first group of channels (CH1 to CH4 in FIG. 26) included in the memory device (12C-1 in FIG. 26). The first memory controller 121C-11 may the data DATA from the first base interface area 121C-21 and output the data DATA to the first internal input and output line MIO1.

The first base interface area 121C-21 may be electrically connected to the first memory controller 121C-11. The first base interface area 121C-21 may receive the command CMD and the data DATA from the first memory controller 121C-11. The first base interface area 121C-21 may output the command CMD and the data DATA to the first base TSV area 121C-31 by adjusting the input and output sequence of the command CMD and the data DATA. The first base interface area 121C-21 may receive the data DATA from the first base TSV area 121C-31 and output the data DATA to the first memory controller 121C-11.

The first base TSV area 121C-31 may be electrically connected to the first base interface area 121C-21. The first base TSV area 121C-31 may receive the command CMD and the data DATA from the first base interface area 121C-21. The first base TSV area 121C-31 may output the command CMD and the data DATA to a first core TSV area (210C-1 in FIG. 26) included in the memory device (12C-1 in FIG. 26) through a plurality of TSVs. The first base TSV area 121C-31 may receive data DATA from the memory device (12C-1 in FIG. 26) and output the data DATA to the first base interface area 121C-21.

The first memory controller 121C-11, the first base interface area 121C-21, and the first base TSV area 121C-31 may be sequentially disposed in a second direction D2 from the first edge area TOP of the control device 11C-1. The second direction D2 may be set as a direction from the first edge area TOP to the central area CENTER. The first edge area TOP may be set as an upper area of the control device 11C-1 in a Y axis.

The second memory controller 122C-11 may be electrically connected to the second internal input and output line MIO2. The second memory controller 122C-11 may receive the command CMD and the data DATA that control an operation of the second group of channels (CH5 to CH8 in FIG. 24) included in the memory device (12C-1 in FIG. 26) through the second internal input and output line MIO2. The second memory controller 122C-11 may output the command CMD and the data DATA that control an operation of the second group of channels (CH5 to CH8 in FIG. 26) included in the memory device (12C-1 in FIG. 24). The second memory controller 122C-11 may receive the data DATA from the second base interface area 122C-21 and output the data DATA to the second internal input and output line MIO2.

The second base interface area 122C-21 may be electrically connected to the second memory controller 122C-11. The second base interface area 122C-21 may receive the command CMD and the data DATA from the second memory controller 122C-11. The second base interface area 122C-21 may output the command CMD and the data DATA to the second base TSV area 122C-31 by adjusting the input and output sequence of the command CMD and the data DATA. The second base interface area 122C-21 may receive the data DATA from the second base TSV area 122C-31 and output the data DATA to the

### Second Memory Controller 121c-21.

The second base TSV area 122C-31 may be electrically connected to the second base interface area 122C-21. The second base TSV area 122C-31 may receive the command CMD and the data DATA from the second base interface area 122C-21. The second base TSV area 122C-31 may output the command CMD and the data DATA to a second core TSV area (220C-1 in FIG. 26) included in the memory device (12C-1 in FIG. 26) through a plurality of TSVs. The second base TSV area 122C-31 may receive the data DATA from the memory device (12C-1 in FIG. 26) and output the data DATA to the second base interface area 122C-21.

The second memory controller 122C-11, the second base interface area 122C-21, and the second base TSV area 122C-31 may be sequentially disposed in a first direction D1 from the second edge area BOTTOM of the control device 11C-1. The first direction D1 may be set as a direction from the second edge area BOTTOM to the central area CENTER. The second edge area BOTTOM may be set as a lower area of the control device 11C-1 in a Y axis.

The second area 120C-1 may be set as an area that receives the command CMD and the data DATA from the first area 110C-1 and outputs the command CMD and the data DATA to the memory device (12C-1 in FIG. 26). The second area 120C-1 may be disposed in the central area CENTER of the control device 11C-1 in the X axis.

The third area 130C-1 may include a second internal interface area (2nd INT IF) 131C-1 and a second physical area (2nd D2D PHY) 132C-1.

The second internal interface area 131C-1 may receive the command CMD and the data DATA from the first internal input and output line MIO1. The second internal interface area 131C-1 may output the command CMD and the data DATA received through the first internal input and output line MIO1 to the second physical area 132C-1 by adjusting the input and output sequence of the command CMD and the data DATA. The second internal interface area 131C-1 may receive the command CMD and the data DATA from the second internal input and output line MIO2. The second internal interface area 131C-1 may output the command CMD and the data DATA received through the second internal input and output line MIO2 to the second physical area 132C-1 by adjusting the input and output sequence of the command CMD and the data DATA. The second internal interface area 131C-1 may be implemented in a network-on-chip (NoC).

The second physical area 132C-1 may receive the command CMD and the data DATA from the second internal interface area 131C-1. The second physical area 132C-1 may output the command CMD that is received as a transfer command TC. The second physical area 132C-1 may output the data DATA that are received as transfer data TD. The second physical area 132C-1 may output the transfer command TC and the transfer data TD to another HBM device and the process circuit (PRC CT in FIGS. 18 and 19).

The third area 130C-1 may be set as an area that receives the command CMD and the data DATA from the second area 120C-1. The third area 130C-1 may be set as an area that inputs and outputs the transfer command TC and the transfer data TD that are generated from the command CMD and the data DATA that are received. The third area 130C-1 may be set as an area that inputs and outputs the command CMD and the data DATA to and from another HBM device, a process circuit, or an external device. The third area 130C-1 may be disposed in a right area RIGHT of the control device 11C-1 in the X axis.

In FIG. 24, the first internal interface area 112C-1, the second internal interface area 131C-1, the first internal input and output line MIO1, and the second internal input and output line MIO2 that are implemented in the network-on-chip (NoC) may be implemented in a first form. The first form means a form in which the first internal input and output line MIO1 and the second internal input and output line MIO2 that are implemented in the transverse direction of the control device 11C-1 in the X axis direction are disposed between the first internal interface area 112C-1 and the second internal interface area 131C-1 that are implemented in the longitudinal direction of the control device 11C-1 in the Y axis direction.

In the first form, the first memory controller 121C-11, the first base interface area 121C-21, and the first base TSV area 121C-31 may be sequentially disposed in the second direction D2 from the first edge area TOP in which the first internal input and output line MIO1 are disposed. In the first form, the second memory controller 122C-11, the second base interface area 122C-21, and the second base TSV area 122C-31 may be sequentially disposed in the first direction D1 from the second edge area BOTTOM in which the second internal input and output line MIO2 is disposed.

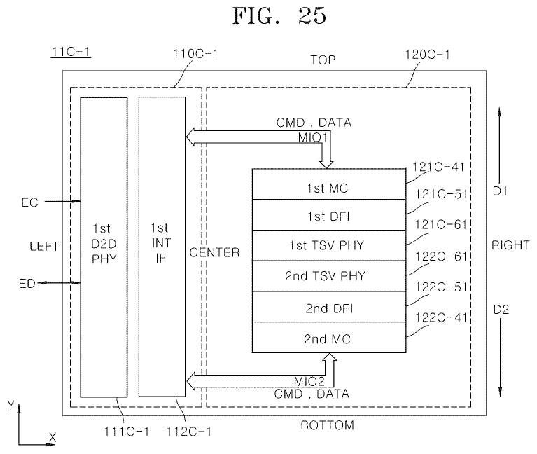

FIG. 25 is a block diagram illustrating a construction of the control device 11C according to an embodiment of the present disclosure. As illustrated in FIG. 25, the control device 11C-1 may include a first area 110C-1 and a second area 120C-1.

The first area 110C-1 may include a first physical area (1st D2D PHY) 111C-1 and a first internal interface area (1st INT IF) 112C-1.

The first physical area 111C-1 and the first internal interface area 112C-1 have the same constructions as the first physical area 111C-1 and the first internal interface area 112C-1 illustrated in FIG. 24, and thus detailed descriptions thereof are omitted.

A first internal input and output line MIO1 illustrated in FIG. 25 is connected between the first internal interface area 112C-1 and a first memory controller (1st MC) 121C-41 differently from the first internal input and output line MIO1 illustrated in FIG. 24, and may input and output a command CMD and data DATA. A second internal input and output line MIO2 illustrated in FIG. 25 is connected between the first internal interface area 112C-1 and a second memory controller (2nd MC) 122C-41 differently from the second internal input and output line MIO2 illustrated in FIG. 24, and may input and output a command CMD and data DATA. The first internal interface area 112C-1, the first internal input and output line MIO1, and the second internal input and output line MIO2 may be implemented in a network-on-chip (NoC).

The first area 110C-1 may be set as an area that generates a command CMD and data DATA and inputs and outputs the command CMD and the data DATA. Heat may be generated when the first area 110C-1 inputs and outputs the command CMD and the data DATA. The first area 110C-1 may be disposed in a left area LEFT of the control device 11C-1 in an X axis.

The second area 120C-1 may include the first memory controller 121C-41, a first base interface area (1st DFI) 121C-51, a first base TSV area (1st TSV PHY) 121C-61, the second memory controller 122C-41, a second base interface area (2nd DFI) 122C-51, and a second base TSV area (2nd TSV PHY) 122C-61 that control an operation of the memory device 12C-1.

The first memory controller 121C-41, the first base interface area 121C-51, the first base TSV area 121C-61, the second memory controller 122C-41, the second base interface area 122C-51, and the second base TSV area 122C-61 have the same constructions as the first memory controller 121C-11, the first base interface area 121C-21, the first base TSV area 121C-31, the second memory controller 122C-11, the second base interface area 122C-21, and the second base TSV area 122C-31 illustrated in FIG. 24, and thus detailed descriptions thereof are omitted.

The second area 120C-1 may be set as an area that receives the command CMD and the data DATA from the first area 110C-1 and outputs the command CMD and the data DATA to the memory device 12C-1. The second area 120C-1 may be disposed in a right area RIGHT of the control device 11C-1 in the X axis.

The first internal interface area 112C-1, the first internal input and output line MIO1, and the second internal input and output line MIO2 that are implemented in the network-on-chip (NoC) illustrated in FIG. 25 may be implemented in a second form. The second form means a form in which the first internal interface area 112C-1 that is implemented in the longitudinal direction of the control device 11C-1 in a Y axis direction and the first internal input and output line MIO1 and the second internal input and output line MIO2 that are implemented in the transverse direction of the control device 11C-1 in the X axis direction are disposed.

In the second form, the first memory controller 121C-41, the first base interface area 121C-51, and the first base TSV area 121C-61 may be sequentially disposed in a second direction D2 from a first edge area TOP in which the first internal input and output line MIO1 is disposed. In the second form, the second memory controller 122C-41, the second base interface area 122C-51, and the second base TSV area 122C-61 may be sequentially disposed in a first direction D1 from a second edge area BOTTOM in which the second internal input and output line MIO2 is disposed.

FIG. 26 is a block diagram illustrating a construction of the memory device 12C-1 according to an embodiment of the present disclosure.

The memory device 12C-1 may include the first to eighth channels CH1 to CH8, the first core TSV area 210C-1, and the second core TSV area 220C-1.

The first to eighth channels CH1 to CH8 may receive a command CMD and data DATA by independently performing internal operations. The first to eighth channels CH1 to CH8 may each store data DATA based on a command CMD after the start of a write operation of an internal operation. The first to eighth channels CH1 to CH8 may each output the data DATA after the start of a read operation of an internal operation based on the command CMD.

The first to fourth channels CH1 to CH4 may be electrically connected to the first core TSV area 210C-1. The first to fourth channels CH1 to CH4 may receive the command CMD and the data DATA from the first core TSV area 210C-1. The first to fourth channels CH1 to CH4 may output the data DATA to the first core TSV area 210C-1. The first to fourth channels CH1 to CH4 may each store the data DATA based on the command CMD after the start of a write operation of an internal operation. The first to fourth channels CH1 to CH4 may each output the data DATA based on the command CMD after the start of a read operation of an internal operation. The first to fourth channels CH1 to CH4 may be set as the first group of channels.

The fifth to eighth channels CH5 to CH8 may be electrically connected to the second core TSV area 220C-1. The fifth to eighth channels CH5 to CH8 may receive a command CMD and data DATA from the second core TSV area 220C-1. The fifth to eighth channels CH5 to CH8 may output the data DATA to the second core TSV area 220C-1. The fifth to eighth channels CH5 to CH8 may each store the data DATA based on the command CMD after the start of a write operation of an internal operation. The fifth to eighth channels CH5 to CH8 may each output the data DATA based on the command CMD after the start of a read operation of an internal operation. The fifth to eighth channels CH5 to CH8 may be set as a second group of channels.

The first to fourth channels CH1 to CH4 may be disposed in a first edge area TOP of the memory device 12C-1. The fifth to eighth channels CH5 to CH8 may be disposed in a second edge area BOTTOM of the memory device 12C.

The first core TSV area 210C-1 may be electrically connected to the first base TSV area 121C-31, 121C-61 of the control device 11C-1. The first core TSV area 210C-1 may receive the command CMD and the data DATA from the first base TSV area 121C-31, 121C-61. The first core TSV area 210C-1 may receive the command CMD and the data DATA through a plurality of TSVs. The first core TSV area 210C-1 may output the command CMD and the data DATA to the first to fourth channels CH1 to CH4. The first core TSV area 210C-1 may receive the data DATA from the first to fourth channels CH1 to CH4 and output the data DATA to the first base TSV area 121C-31, 121C-61. The first core TSV area 210C-1 may be disposed in a central area CENTER. The first core TSV area 210C-1 may be disposed in a second direction D2 from the first edge area TOP. The second direction D2 may be set as a direction of from the first edge area TOP to the central area CENTER. The first edge area TOP may be set as an upper area of the memory device 12C-1 in a Y axis.

The second core TSV area 220C-1 may be electrically connected to the second base TSV area 122C-31, 122C-61 of the control device 11C-1. The second core TSV area 220C-1 may receive the command CMD and the data DATA from the second base TSV area 122C-31, 122C-61. The second core TSV area 220C-1 may receive the command CMD and the data DATA through a plurality of TSVs. The second core TSV area 220C-1 may output the command CMD and the data DATA to the fifth to eighth channels CH5 to CH8. The second core TSV area 220C-1 may receive the data DATA from the fifth to eighth channels CH5 to CH8 and output the data DATA to the second base TSV area 122C-31, 122C-61. The second core TSV area 220C-1 may be disposed in the central area CENTER. The second core TSV area 220C-1 may be disposed in a first direction D1 from the second edge area BOTTOM. The first direction D1 may be set as a direction from the second edge area BOTTOM to the central area CENTER. The second edge area BOTTOM may be set as a lower area of the memory device 12C-1 in the Y axis.

The HBM device 7C according to an embodiment of the present disclosure can prevent a phenomenon in which generated heat is diffused to a memory device because the memory device is not stacked on an area from which the heat is generated due to the input and output of the command CMD and the data DATA. The HBM device 7C according to an embodiment of the present disclosure can facilitate the discharge of heat because a dummy die group is stacked on an area from which the heat is generated due to the input and output of the command CMD and the data DATA.

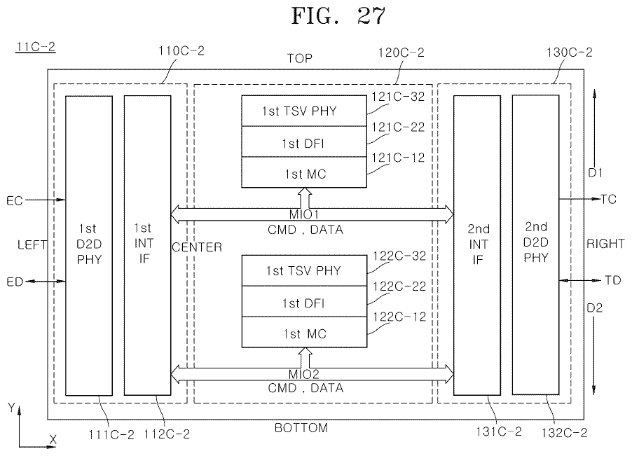

FIG. 27 is a block diagram illustrating a construction of the control device 11C-2 according to an embodiment of the present disclosure. As illustrated in FIG. 27, the control device 11C-2 may include a first area 110C-2, a second area 120C-2, and a third area 130C-2.

The first area 110C-2 may include a first physical area (1st D2D PHY) 111C-2 and a first internal interface area (1st INT IF) 112C-2.

The first physical area 111C-2 may generate a command CMD by receiving an external command EC from the process circuit (PRC CT in FIGS. 18 and 19). The first physical area 111C-2 may generate the command CMD by buffering or decoding the external command EC. The external command EC and the command CMD are each illustrated as only one signal, but may each include a plurality of bits. The first physical area 111C-2 may generate data DATA by receiving external data ED from the process circuit (PRC CT in FIGS. 18 and 19). The first physical area 111C-2 may generate the external data ED by receiving data DATA from the first internal interface area 112C-2. The first physical area 111C-2 may output the external data ED to the process circuit (PRC CT in FIGS. 18 and 19). The external data ED and the data DATA are each illustrated as only one signal, but may each include a plurality of bits.

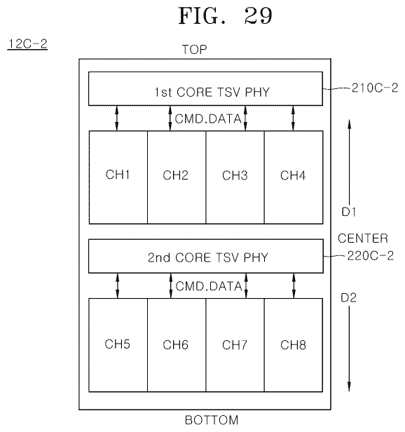

The first internal interface area 112C-2 may receive the command CMD and the data DATA from the first physical area 111C-2. The first internal interface area 112C-2 may output the command CMD and the data DATA that control an operation of the memory device (12C-2 in FIG. 26) to a first internal input and output line MIO1 by adjusting the input and output sequence of the command CMD and the data DATA. The first internal interface area 112C-2 may output the command CMD and the data DATA that control an operation of the memory device (12C-2 in FIG. 29) to a second internal input and output line MIO2 by adjusting the input and output sequence of the command CMD and the data DATA. The first internal input and output line MIO1 may be disposed in a central area CENTER of the control device 111C-2. The second internal input and output line MIO2 may be disposed in a second edge area BOTTOM of the control device 11C-2. The first internal interface area 112C-2, the first internal input and output line MIO1, and the second internal input and output line MIO2 may be implemented in a network-on-chip (NoC).

The first area 110C-2 may be set as an area that generates a command CMD and data DATA and inputs and outputs the command CMD and the data DATA. Heat may be generated when the first area 110C-2 inputs and outputs the command CMD and the data DATA. The first area 110C-12 may be disposed in a left area LEFT of the control device 11C-2 in an X axis.

The second area 120C-2 may include a first memory controller (1st MC) 121C-12, a first base interface area (1st DFI) 121C-22, a first base TSV area (1st TSV PHY) 121C-32, a second memory controller (2nd MC) 122C-12, a second base interface area (2nd DFI) 122C-22, and a second base TSV area (2nd TSV PHY) 122C-32 that control an operation of the memory device (12C-2 in FIG. 29). The first memory controller 121C-12, the first base interface area 121C-22, and the first base TSV area 121C-32 may be components that control an operation of a first group of channels (CH1 to CH4 in FIG. 29) included in a memory device (12C-2 in FIG. 29). The second memory controller 122C-12, the second base interface area 122C-22, and the second base TSV area 122C-32 may be components that control an operation of the second group of channels (CH5 to CH8 in FIG. 29) included in the memory device (12C-2 in FIG. 29). Each of the first memory controller 121C-12, the first base interface area 121C-22, and the first base TSV area 121C-32, and the second memory controller 122C-12, the second base interface area 122C-22, and the second base TSV area 122C-32 may be implemented with the memory controller 121C, the base interface area 122C, and the base TSV area 123C illustrated in FIG. 20.

The first memory controller 121C-12, the first base interface area 121C-22, the first base TSV area 121C-32, the second memory controller 122C-12, the second base interface area 122C-22, and the second base TSV area 122C-32 may be disposed in the horizontal direction of the control device 11C-2.

The first memory controller 121C-12 may be electrically connected to the first internal input and output line MIO1. The first memory controller 121C-12 may receive the command CMD and the data DATA that control an operation of the first group of channels (CH1 to CH4 in FIG. 29) included in the memory device (12C-2 in FIG. 29) through the first internal input and output line MIO1. The first memory controller 121C-12 may output the command CMD and the data DATA that control an operation of the first group of channels (CH1 to CH4 in FIG. 29) included in the memory device (12C-2 in FIG. 29). The first memory controller 121C-12 may receive the data DATA from the first base interface area 121C-22 and output the data DATA to the first internal input and output line MIO1.

The first base interface area 121C-22 may be electrically connected to the first memory controller 121C-12. The first base interface area 121C-22 may receive the command CMD and the data DATA from the first memory controller 121C-12. The first base interface area 121C-22 may output the command CMD and the data DATA to the first base TSV area 121C-32 by adjusting the input and output sequence of the command CMD and the data DATA. The first base interface area 121C-22 may receive the data DATA from the first base TSV area 121C-32 and output the data DATA to the first memory controller 121C-12.

The first base TSV area 121C-32 may be electrically connected to the first base interface area 121C-22. The first base TSV area 121C-32 may receive the command CMD and the data DATA from the first base interface area 121C-22. The first base TSV area 121C-32 may output the command CMD and the data DATA to a first core TSV area (1st CORE TSV PHY) (210C-2 in FIG. 29) included in the memory device (12C-2 in FIG. 29) through a plurality of TSVs. The first base TSV area 121C-32 may receive data DATA from the memory device (12C-2 in FIG. 29) and output the data DATA to the first base interface area 121C-22.

The first memory controller 121C-12, the first base interface area 121C-22, and the first base TSV area 121C-32 may be sequentially disposed in a first direction D1 from the central area CENTER of the control device 11C-2. The first direction D1 may be set as a direction from the central area CENTER to a first edge area TOP. The first edge area TOP may be set as an upper area of the control device 11C-2 in a Y axis.

The second memory controller 122C-12 may be electrically connected to the second internal input and output line MIO2. The second memory controller 122C-12 may receive the command CMD and the data DATA that control an operation of a second group of channels (CH5 to CH8 in FIG. 29) included in the memory device (12C-2 in FIG. 29) through the second internal input and output line MIO2. The second memory controller 122C-12 may output the command CMD and the data DATA that control an operation of the second group of channels (CH5 to CH8 in FIG. 29) included in the memory device (12C-2 in FIG. 29). The second memory controller 122C-12 may receive the data DATA from the second base interface area 122C-22 and output the data DATA to the second internal input and output line MIO2.

The second base interface area 122C-22 may be electrically connected to the second memory controller 122C-12. The second base interface area 122C-22 may receive the command CMD and the data DATA from the second memory controller 122C-12. The second base interface area 122C-22 may output the command CMD and the data DATA to the second base TSV area 122C-32 by adjusting the input and output sequence of the command CMD and the data DATA. The second base interface area 122C-22 may receive the data DATA from the second base TSV area 122C-32 and output the data DATA to the second memory controller 121C-22.

The second base TSV area 122C-32 may be electrically connected to the second base interface area 122C-22. The second base TSV area 122C-32 may receive the command CMD and the data DATA from the second base interface area 122C-22. The second base TSV area 122C-32 may output the command CMD and the data DATA to a second core TSV area (2nd CORE TSV PHY) (220C-2 in FIG. 29) included in the memory device (12C-2 in FIG. 29) through a plurality of TSVs. The second base TSV area 122C-32 may receive the data DATA from the memory device (12C-2 in FIG. 29) and output the data DATA to the second base interface area 122C-22.

The second memory controller 122C-12, the second base interface area 122C-22, and the second base TSV area 122C-32 may be sequentially disposed in the first direction D1 from the second edge area BOTTOM of the control device 11C-2. The first direction D1 may be set as a direction from the second edge area BOTTOM to the central area CENTER. The second edge area BOTTOM may be set as a lower area of the control device 11C-2 in the Y axis.

The second area 120C-2 may be set as an area that receives the command CMD and the data DATA from the first area 110C-2 and outputs the command CMD and the data DATA to the memory device (12C-2 in FIG. 29). The second area 120C-2 may be disposed in the central area CENTER of the control device 11C-2 in the X axis.

The third area 130C-2 may include a second internal interface area (2nd INT IF) 131C-2 and a second physical area (2nd D2D PHY) 132C-2.

The second internal interface area 131C-2 may receive the command CMD and the data DATA from the first internal input and output line MIO1. The second internal interface area 131C-2 may output the command CMD and the data DATA received through the first internal input and output line MIO1 to the second physical area 132C-2 by adjusting the input and output sequence of the command CMD and the data DATA. The second internal interface area 131C-2 may receive the command CMD and the data DATA from the second internal input and output line MIO2. The second internal interface area 131C-2 may output the command CMD and the data DATA received through the second internal input and output line MIO2 to the second physical area 132C-2 by adjusting the input and output sequence of the command CMD and the data DATA. The second internal interface area 131C-2 may be implemented in a network-on-chip (NoC).

The second physical area 132C-2 may receive the command CMD and the data DATA from the second internal interface area 131C-2. The second physical area 132C-2 may output the command CMD that is received as a transfer command TC. The second physical area 132C-2 may output the data DATA that are received as transfer data TD. The second physical area 132C-2 may output the transfer command TC and the transfer data TD to another HBM device and the process circuit (PRC CT in FIGS. 18 and 19).

The third area 130C-2 may be set as an area that receives the command CMD and the data DATA from the second area 120C-2. The third area 130C-2 may be set as an area that inputs and outputs the transfer command TC and the transfer data TD that are generated from the command CMD and the data DATA that are received. The third area 130C-2 may be set as an area that inputs and outputs the command CMD and the data DATA to and from another HBM device, a process circuit, or an external device. The third area 130C-2 may be disposed in a right area RIGHT of the control device 11C-2 in the X axis.

In FIG. 27, the first internal interface area 112C-2, the second internal interface area 131C-2, the first internal input and output line MIO1, and the second internal input and output line MIO2 that are implemented in the network-on-chip (NoC) may be implemented in a first form. The first form means a form in which the first internal input and output line MIO1 and the second internal input and output line MIO2 that are implemented in the transverse direction of the control device 11C-2 in the X axis direction are disposed between the first internal interface area 112C-2 and the second internal interface area 131C-2 that are implemented in the longitudinal direction of the control device 11C-2 in the Y axis direction.

In the first form, the first memory controller 121C-12, the first base interface area 121C-22, and the first base TSV area 121C-32 may be sequentially disposed in the first direction D1 from the central area CENTER in which the first internal input and output line MIO1 is disposed. In the first form, the second memory controller 122C-12, the second base interface area 122C-22, and the second base TSV area 122C-32 may be sequentially disposed in the first direction D1 from the second edge area BOTTOM in which the second internal input and output line MIO2 is disposed.

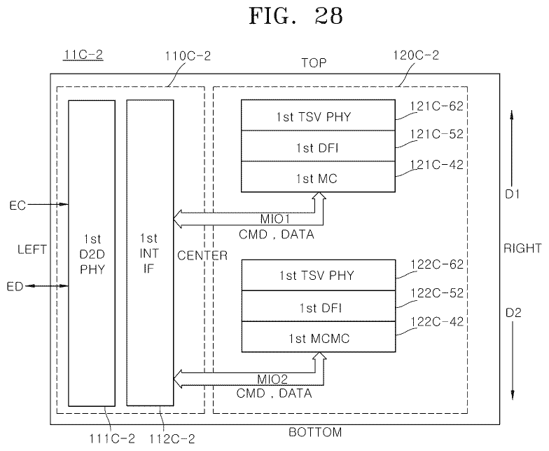

FIG. 28 is a block diagram illustrating a construction of the control device 11C according to an embodiment of the present disclosure. As illustrated in FIG. 28, a control device 11C-2 may include a first area 110C-2 and a second area 120C-2.

The first area 110C-2 may include a first physical area (1st D2D PHY) 111C-2 and a first internal interface area (1st INT IF) 112C-2.

The first physical area 111C-2 and the first internal interface area 112C-2 have the same constructions as the first physical area 111C-2 and the first internal interface area 112C-2 illustrated in FIG. 27, and thus detailed descriptions thereof are omitted.

A first internal input and output line MIO1 illustrated in FIG. 28 is connected between the first internal interface area 112C-2 and a first memory controller (1st MC) 121C-42 differently from the first internal input and output line MIO1 illustrated in FIG. 27, and may input and output a command CMD and data DATA. A second internal input and output line MIO2 illustrated in FIG. 28 is connected between the first internal interface area 112C-2 and a second memory controller (2nd MC) 122C-42 differently from the second internal input and output line MIO2 illustrated in FIG. 27, and may input and output a command CMD and data DATA. The first internal interface area 112C-2, the first internal input and output line MIO1 and the second internal input and output line MIO2 may be implemented in a network-on-chip (NoC).

The first area 110C-2 may be set as an area that generates a command CMD and data DATA and inputs and outputs the command CMD and the data DATA. Heat may be generated when the first area 110C-2 inputs and outputs the command CMD and the data DATA. The first area 110C-2 may be disposed in a left area LEFT of the control device 11C-2 in an X axis.

The second area 120C-2 may include the first memory controller 121C-42, a first base interface area (1st DFI) 121C-52, a first base TSV area (1st TSV PHY) 121C-62, the second memory controller 122C-42, a second base interface area (2nd DFI) 122C-52, and a second base TSV area (2nd TSV PHY) 122C-62 that control an operation of the memory device (12C-2 in FIG. 29).

The first memory controller 121C-42, the first base interface area 121C-52, the first base TSV area 121C-62, the second memory controller 122C-42, the second base interface area 122C-52, and the second base TSV area 122C-62 have the same constructions as the first memory controller 121C-12, the first base interface area 121C-22, the first base TSV area 121C-32, the second memory controller 122C-12, the second base interface area 122C-22, and the second base TSV area 122C-32 illustrated in FIG. 27, and thus detailed descriptions thereof are omitted.

The second area 120C-2 may be set as an area that receives the command CMD and the data DATA from the first area 110C-2 and outputs the command CMD and the data DATA to the memory device 12C-2. The second area 120C-2 may be disposed in a right area RIGHT of the control device 11C-2 in the X axis.

The first internal interface area 112C-2, the first internal input and output line MIO1, and the second internal input and output line MIO2 that are implemented with a network-on-chip (NoC), which are illustrated in FIG. 28, may be implemented in a second form. The second form means a form in which the first internal interface area 112C-2 that is implemented in the longitudinal direction of the control device 11C-2 in a Y axis direction and the first internal input and output line MIO1, the second internal input and output line MIO2 that are implemented in the transverse direction of the control device 11C-2 in the X axis direction are disposed.

In the second form, the first memory controller 121C-42, the first base interface area 121C-52, and the first base TSV area 121C-62 may be sequentially disposed in a first direction D1 from the central area CENTER in which the first internal input and output line MIO1 is disposed. In the second form, the second memory controller 122C-42, the second base interface area 122C-52, and the second base TSV area 122C-62 may be sequentially disposed in the first direction D1 from a second edge area BOTTOM in which the second internal input and output line MIO2 is disposed.

FIG. 29 is a block diagram illustrating a construction of the memory device 12C-2 according to an embodiment of the present disclosure.

The memory device 12C-2 may include the first to eighth channels CH1 to CH8, the first core TSV area 210C-2, and a second core TSV area (2nd CORE TSV PHY) 220C-2.

The first to eighth channels CH1 to CH8 may receive the command CMD and the data DATA by independently performing internal operations. The first to eighth channels CH1 to CH8 may each store the data DATA after the start of a write operation of an internal operation based on the command CMD. The first to eighth channels CH1 to CH8 may each output the data DATA after the start of a read operation of an internal operation based on the command CMD.

The first to fourth channels CH1 to CH4 may be electrically connected to the first core TSV area 210C-2. The first to fourth channels CH1 to CH4 may receive the command CMD and the data DATA from the first core TSV area 210C-2. The first to fourth channels CH1 to CH4 may output the data DATA to the first core TSV area 210C-2. The first to fourth channels CH1 to CH4 may each store the data DATA based on the command CMD after the start of a write operation of an internal operation. The first to fourth channels CH1 to CH4 may each output the data DATA based on the command CMD after the start of a read operation of an internal operation. The first to fourth channels CH1 to CH4 may be set as the first group of channels.

The fifth to eighth channels CH5 to CH8 may be electrically connected to the second core TSV area 220C-2. The fifth to eighth channels CH5 to CH8 may receive a command CMD and data DATA from the second core TSV area 220C-2. The fifth to eighth channels CH5 to CH8 may output the data DATA to the second core TSV area 220C-2. The fifth to eighth channels CH5 to CH8 may each store the data DATA based on the command CMD after the start of a write operation of an internal operation. The fifth to eighth channels CH5 to CH8 may each output the data DATA based on the command CMD after the start of a read operation of an internal operation. The fifth to eighth channels CH5 to CH8 may be set as the second group of channels.

The first to fourth channels CH1 to CH4 may be disposed in a central area CENTER of the memory device 12C-2. The fifth to eighth channels CH5 to CH8 may be disposed in a second edge area BOTTOM of the memory device 12C-2.

The first core TSV area 210C-2 may be electrically connected to the first base TSV area 121C-32, 121C-62 of the control device 11C-2. The first core TSV area 210C-2 may receive the command CMD and the data DATA from the first base TSV area 121C-32, 121C-62. The first core TSV area 210C-2 may receive the command CMD and the data DATA through a plurality of TSVs. The first core TSV area 210C-2 may output the command CMD and the data DATA to the first to fourth channels CH1 to CH4. The first core TSV area 210-2 may receive the data DATA from the first to fourth channels CH1 to CH4 and output the data DATA to the first base TSV area 121C-32, 121C-62. The first core TSV area 210C-2 may be disposed in a first direction D1 from the central area CENTER. The first direction D1 may be set as a direction from the central area CENTER to a first edge area TOP. The first edge area TOP may be set as an upper area of the memory device 12C-2 in a Y axis.

The second core TSV area 220C-2 may be electrically connected to the second base TSV area 122C-32, 122C-62 of the control device 11C-2. The second core TSV area 220C-2 may receive the command CMD and the data DATA from the second base TSV area 122C-32, 122C-62. The second core TSV area 220C-2 may receive the command CMD and the data DATA through a plurality of TSVs. The second core TSV area 220C-2 may output the command CMD and the data DATA to the fifth to eighth channels CH5 to CH8. The second core TSV area 220C-2 may receive the data DATA from the fifth to eighth channels CH5 to CH8 and output the data DATA to the second base TSV area 122C-32, 122C-62. The second core TSV area 220C-2 may be disposed in the central area CENTER. The second core TSV area 220C-2 may be disposed in the first direction D1 from the second edge area BOTTOM. The first direction D1 may be set as a direction from the second edge area BOTTOM to the central area CENTER. The second edge area BOTTOM may be set as a lower area of the memory device 12C-2 in the Y axis.

The HBM device 7C according to an embodiment of the present disclosure can prevent a phenomenon in which generated heat is diffused to a memory device because the memory device is not stacked on an area from which the heat is generated due to the input and output of the command CMD and the data DATA. The HBM device 7C according to an embodiment of the present disclosure can facilitate the discharge of heat because a dummy die group is stacked on an area from which the heat is generated due to the input and output of the command CMD and the data DATA.

What is claimed is:

1. A semiconductor system comprising:
a control device including a first area and a second area, the first area comprising an internal interface area disposed in a first direction and the second area comprising an internal input and output line disposed in a second direction; and
a memory device stacked on the second area and configured to input and output data,
wherein the internal input and output line intersects with the internal interface area to connect to the interface area and the intersection of the internal input and output line with the internal interface area is substantially orthogonal,
wherein the control device and the memory device are configured to input and output the data to and from the internal interface area through the internal input and output line, and
a setting space is set vertically to the first area.

2. The semiconductor system of claim 1, further comprising a dummy die group including a plurality of dummy dies that are vertically stacked with one another, the dummy die group disposed in the setting space that is located on the first area.

3. The semiconductor system of claim 1, wherein one dummy die from the plurality of dummy dies is disposed in the setting space located on the first area.

4. The semiconductor system of claim 1, wherein the setting space that is vertically set on the first area is set as an empty space.

5. The semiconductor system of claim 1,
wherein the control device comprises:
a physical area configured to input and output the data;
a memory controller electrically connected to the internal input and output line and the base interface area and configured to input and output the data; and
a base interface area electrically connected to the memory controller and a base through silicon via (TSV) area and configured to input and output the data,
wherein the internal interface area is electrically connected to the physical area and the internal input and output line and is configured to input and output the data, and
wherein the base TSV area is electrically connected to the base interface area and the memory device and is configured to input and output the data.

6. The semiconductor system of claim 5, wherein:
the physical area and the internal interface area are disposed in the first area, and
the internal input and output line, the memory controller, the base interface area, and the base TSV area are disposed in the second area.

7. The semiconductor system of claim 5, wherein:
the internal input and output line is disposed in a central area of the second area of the control device, and
the memory controller, the base interface area, and the base TSV area are sequentially disposed in the first direction from the central area of the control device, wherein the first direction is a direction from the central area of the control device to an edge area of the control device.

8. The semiconductor system of claim 5,
wherein the internal input and output line is disposed in an edge area of the second area of the control device,
wherein the memory controller, the base interface area, and the base TSV area are sequentially disposed in the first direction from the edge area of the control device, and
wherein the first direction is a direction from the edge area of the control device to the central area of the control device.

9. The semiconductor system of claim 5, wherein:
the memory device comprises a plurality of channels and a core TSV area, and
the core TSV area is electrically connected to the plurality of channels and the base TSV area and is configured to input and output the data.

10. The semiconductor system of claim 9,
wherein the plurality of channels are disposed in a central area of the memory device, and
wherein the core TSV area is disposed in an edge area of the memory device,
wherein the edge area is set in the first direction from the central area of the memory device, and
wherein the first direction is a direction from the central area of the memory device to the edge area of the memory device.

11. The semiconductor system of claim 9,
wherein the plurality of channels are disposed in an edge area of the memory device, and
wherein the core TSV area is disposed in a central area of the memory device,
wherein the edge area is set in the first direction from the central area of the memory device, and
wherein the first direction is a direction from the edge area of the memory device to the central area of the memory device.

12. A semiconductor system comprising:
a control device including first to third areas, the first area comprising a first internal interface area disposed in a first direction, the second area comprising first and second internal input and output lines disposed in a second direction, and the third area comprising a second internal interface area disposed in the first direction; and
a memory device stacked on the second area and configured to input and output first and second data,
wherein the first and second internal interface areas and the first and second internal input and output lines are connected in an orthogonal direction to each other,
wherein the control device and the memory device are configured to input and output the first and second data to and from the first and second internal interface areas through the first and second internal input and output lines,
a first setting space is set vertically to the first area,
a second setting space is set vertically to the second area, and
a third setting space is set vertically to the third area.

13. The semiconductor system of claim 12, further comprising:
a first dummy die group including a first plurality of dummy dies that are vertically stacked with one another, the first dummy die group disposed in the first setting space that is located on the first area, and
a second dummy die group including a second plurality of dummy dies that are vertically stacked with one another, the second dummy die group disposed in the third setting space that is located on the third area.

14. The semiconductor system of claim 12, wherein:
one first dummy die from the first plurality of dummy dies is disposed in the first setting space located on the first area, and
one second dummy die from the second plurality of dummy dies is disposed in the third setting space located on the third area.

15. The semiconductor system of claim 12, wherein the first setting space that is vertically set on the first area and the third setting space that is vertically set on the third area are set as an empty space.

16. The semiconductor system of claim 12, wherein:
a dummy die group including a plurality of dummy dies vertically stacked with one another are disposed in the first setting space located on the first area, and
the third setting space located on the third area is set as an empty space.

17. The semiconductor system of claim 12, wherein the control device comprises:
wherein the control device comprises a first physical area configured to input and output the first and second data;
wherein the first internal interface area is electrically connected to the first physical area and the first and second internal input and output lines and is configured to input and output the first and second data;
wherein the control device comprises a memory controller electrically connected to the first internal input and output line and the base interface area and is configured to input and output the first data;
wherein the control device comprises a base interface area electrically connected to the memory controller and a base through silicon via (TSV) area and is configured to input and output the first data;
wherein the base TSV area is electrically connected to the base interface area and the memory device and is configured to input and output the data,
wherein the second internal interface area is electrically connected to the second internal input and output line and a second physical area and is configured to input and output the second data, and
wherein the second physical area is configured to input and output the second data.

18. The semiconductor system of claim 17, wherein:
the first physical area and the first internal interface area are disposed in the first area,
the first and second internal input and output lines, the memory controller, the base interface area, and the base TSV area are disposed in the second area, and
the second internal interface area and the second physical area are disposed in the third area.

19. The semiconductor system of claim 18, wherein:
the first and second internal input and output lines are disposed in a central area of the second area of the control device, and
the memory controller, the base interface area, and the base TSV area are sequentially disposed in the first direction from the central area of the control device, wherein the first direction is a direction from the central area of the control device to an edge area of the control device.

20. The semiconductor system of claim 18, wherein:
the first internal input and output line is disposed in a central area of the second area of the control device,
the second internal input and output line is disposed in an edge area of the second area of the control device, and
the memory controller, the base interface area, and the base TSV area are sequentially disposed in the first direction from the central area of the control device, wherein the first direction is set as a direction from the central area of the control device to the edge area of the control device.

21. The semiconductor system of claim 18, wherein:
the first internal input and output line are disposed in an edge area of the second area of the control device,
the second internal input and output line is disposed in a central area of the second area of the control device, and
the memory controller, the base interface area, and the base TSV area are sequentially disposed in the first direction from the edge area of the control device, wherein the first direction is a direction from the edge area of the control device to the central area of the control device.

22. The semiconductor system of claim 17, wherein:
the memory device comprises a plurality of channels and a core through silicon via (TSV) area, and
the core TSV area is electrically connected to the plurality of channels and the base TSV area and is configured to input and output the first data.

23. The semiconductor system of claim 22,
wherein the plurality of channels are disposed in a central area of the memory device, and
wherein the core TSV area is disposed in an edge area of the memory device, and
wherein the edge area of the memory device is located in the first direction from the central area of the memory device.

24. The semiconductor system of claim 22,
wherein the plurality of channels is disposed in an edge area of the memory device, and
wherein the core TSV area is disposed in a central area of the memory device, and
wherein the edge area of the memory device is located in the first direction from the central area of the memory device.

25. A semiconductor system comprising:
a control device including a first area and a second area, the first area comprising an internal interface area disposed in a first direction and the second area comprising first and second internal input and output lines disposed in a second direction; and
a memory device stacked on the second area and configured to input and output data,
wherein the internal interface area and the first and second internal input and output lines are connected in an orthogonal direction to each other,
wherein the control device and the memory device are configured to input and output the data to and from the internal interface area through the first and second internal input and output lines,
a first setting space is set vertically to the first area, and
a second setting space is set vertically to the second area.

26. A semiconductor system comprising:
a control device including first to third areas, the first area comprising a first internal interface area disposed in a first direction, the second area comprising an internal input and output line disposed in a second direction, and the third area comprising a second internal interface area disposed in the first direction; and
a memory device stacked on the second area and configured to input and output first and second data,
wherein the first and second internal interface areas and the internal input and output line are connected in an orthogonal direction to each other,
wherein the control device and the memory device are configured to input and output the first and second data to and from the first and second internal interface areas through the internal input and output line,
a first setting space is set vertically to the first area,
a second setting space is set vertically to the second area, and
a third setting space is set vertically to the third area.
